(19) United States
(12) Patent Application Publication
(10) Pub. No.: US 2026/0136678 A1
(43) Pub. Date: May 14, 2026

(54) Debonding Techniques for Stacked Device Structures

(71) Applicant: Taiwan Semiconductor Manufacturing Company, Ltd., Hsin-Chu (TW)

(72) Inventors: Che Chi SHIH, Taoyuan City (TW); Kuan-Kan HU, Hsinchu (TW); Ku-Feng YANG, Hsinchu City (TW); Szuya LIAO, Hsinchu (TW)

(21) Appl. No.: 19/170,486

(22) Filed: Apr. 4, 2025

Related U.S. Application Data
(60) Provisional application No. 63/719,906, filed on Nov. 13, 2024.

(51) Int. Cl. H10D 88/00; B23K 26/36

(52) U.S. Cl. CPC H10D 88/01; B23K 26/36

(57) ABSTRACT

A method includes receiving a first device component, receiving a second device component, and bonding a semiconductor layer stack of the first device component and the second device component to form a first stacked structure. The first device component includes a release layer disposed between the semiconductor layer stack and a first substrate, and the first stacked structure includes the semiconductor layer stack disposed between the release layer and the second device component. The method includes, after the bonding, removing the first substrate and the release layer from the first stacked structure, and reusing the first substrate to form a second stacked structure. An example release layer is a two-dimensional layer, which facilitates removal of the first substrate and the release layer by peeling. Another example release layer is a semiconductor oxide layer/region, which facilitates removal of the first substrate and the release layer by laser treatment.

This is a non-provisional application of and claims benefit of U.S. Provisional Patent Application Ser. No. 63/719,906, filed Nov. 13, 2024, the entire disclosure of which is incorporated herein by reference.

### BACKGROUND

The electronics industry has experienced an ever-increasing demand for smaller and faster electronic devices that are simultaneously able to support a greater number of increasingly complex and sophisticated functions. To meet these demands, there is a continuing trend in the integrated circuit (IC) industry to manufacture low-cost, high-performance, and low-power ICs. Thus far, these goals have been achieved in large part by reducing IC dimensions (for example, by reducing minimum IC feature size), thereby improving production efficiency and lowering associated costs. However, such scaling has also increased complexity of IC manufacturing processes. Thus, realizing continued advances in IC devices and their performance requires similar advances in IC manufacturing processes and technology.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1A is a cross-sectional view of a stacked device structure, in portion or entirety, according to various aspects of the present disclosure.

FIG. 1B is a cross-sectional view of another stacked device structure, in portion or entirety, according to various aspects of the present disclosure.

FIG. 2 is a flow chart of a method, in portion or entirety, for preparing a stacked structure for use in fabricating a stacked device structure, such as the stacked device structure of

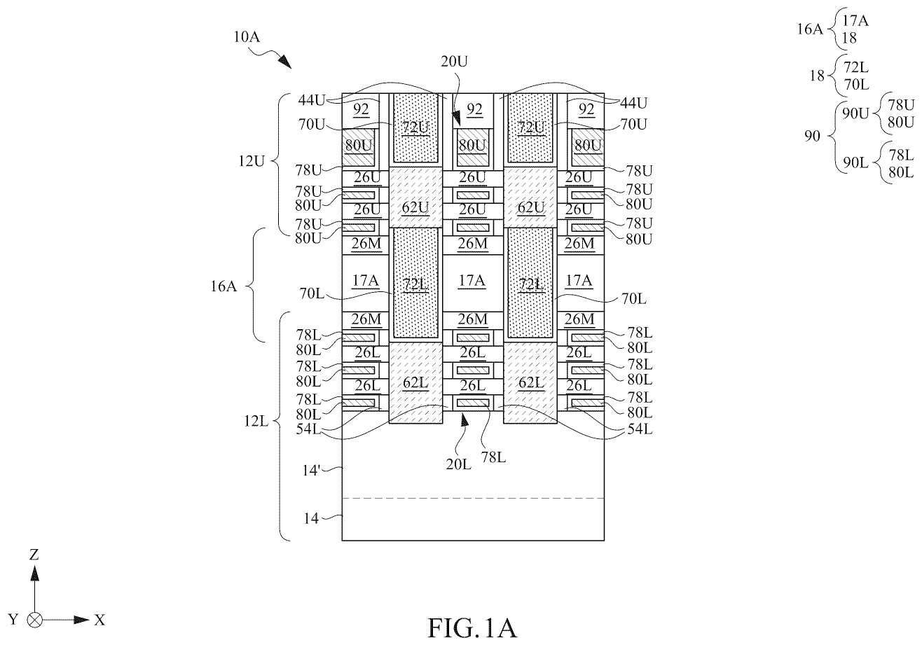

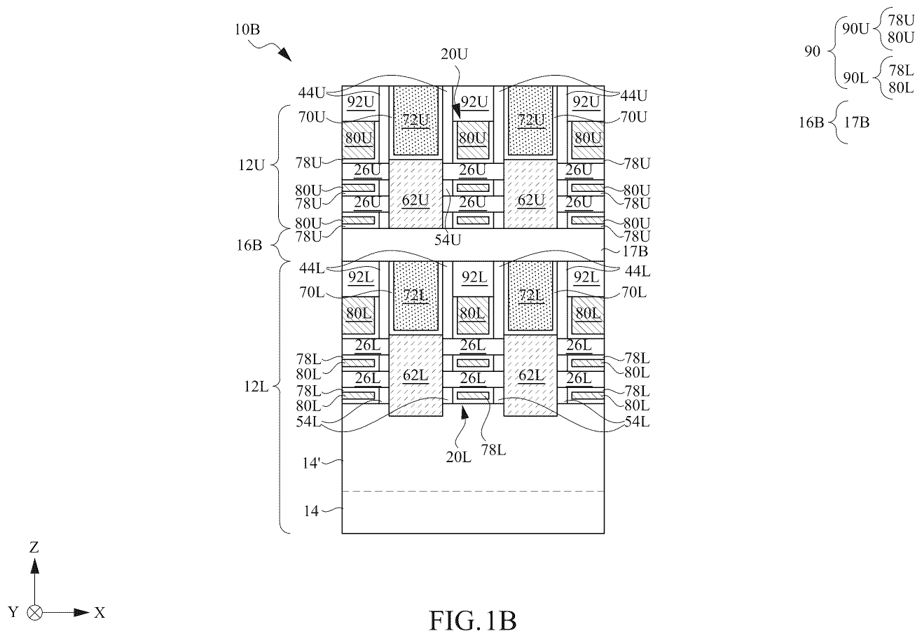

FIG. 1A and/or the stacked device structure of FIG. 1B, that implements a debonding technique that facilitates carrier substrate reuse, according to various aspects of the present disclosure.

FIGS. 3A-3K illustrate a process flow, in portion or entirety, for preparing stacked structures, according to various aspects of the present disclosure.

FIG. 4 illustrates a process flow, in portion or entirety, for reusing carrier substrates of stacked structures, according to various aspects of the present disclosure.

FIGS. 5A-5J illustrate yet another process flow, in portion or entirety, for preparing stacked structures, according to various aspects of the present disclosure.

FIGS. 6A-6M illustrate yet another process flow, in portion or entirety, for preparing stacked structures, according to various aspects of the present disclosure.

FIGS. 7A-7M illustrate yet another process flow, in portion or entirety, for preparing stacked structures, according to various aspects of the present disclosure.

FIGS. 8A-8K illustrate yet another process flow, in portion or entirety, for preparing stacked structures, according to various aspects of the present disclosure.

FIGS. 9A-9F are cross-sectional views of a stacked device structure, in portion or entirety, at various fabrication stages, according to various aspects of the present disclosure.

FIGS. 10A-10D are cross-sectional views of a stacked device structure, in portion or entirety, at various fabrication stages, according to various aspects of the present disclosure.

### DETAILED DESCRIPTION

The present disclosure relates generally to debonding techniques for stacked device structures, such as stacked transistors, that enable reuse of carrier substrates.

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. The present disclosure may also repeat reference numerals and/or letters in the various examples. This repetition is for the purpose of simplicity and clarity and does not in itself dictate a relationship between the various embodiments and/or configurations discussed.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−20% of the number described, based on known manufacturing tolerances associated with manufacturing a feature having a characteristic associated with the number. For example, a material layer having a thickness of “about 5 nm” may encompass a dimension range from 4.5 nm to 5.5 nm where manufacturing tolerances associated with depositing the material layer are known to be +/−10% by one of ordinary skill in the art. Furthermore, given the variances inherent in any manufacturing process, when device features are described as having “substantial” properties and/or characteristics, such term is intended to capture properties and/or characteristics that are within tolerances of manufacturing processes. For example, “substantially vertical” or “substantially horizontal” features are intended to capture features that are approximately vertical and horizontal within given tolerances of the manufacturing processes used to fabricate such features-but not mathematically or perfectly vertical and horizontal.

Stacked device structures provide further density reduction for advanced integrated circuit (IC) technology nodes (particularly as they advance to 3 nm (N3) and below), especially when the stacked device structures include multigate devices, such as fin-like field effect transistors (FinFETs), gate-all-around (GAA) transistors including nanowires and/or nanosheets, other types of multigate devices, etc. Stacked device structures vertically stack devices, such as transistors. For example, a transistor stack may include a first transistor (e.g., a top transistor) disposed over a second transistor (e.g., a bottom transistor). The transistor stack may provide a complementary field effect transistor (CFET) when the first transistor and the second transistor are of opposite conductivity type (i.e., an n-type transistor and a p-type transistor).

The present disclosure is generally directed to debonding techniques for stacked device structures, such as stacked transistors (e.g., CFETs). For example, debonding techniques are disclosed herein that may reduce costs associated with fabricating stacked device structures, for example, by enabling multiple uses of a carrier substrate when preparing semiconductor layer stack precursors, which are processed to form the stacked device structures. The disclosed debonding techniques implement peeling (via a two-dimensional material) or laser treatment (via a semiconductor oxide layer/region), as described herein, to minimize damage to the semiconductor layer stack precursors and/or the carrier substrate. Different embodiments may have different advantages, and no particular advantage is required of any embodiment.

FIG. 1A is a cross-sectional view of a stacked device structure 10A, in portion or entirety, according to various aspects of the present disclosure. Stacked device structure 10A is fabricated monolithically, and thus may be referred to as a monolithic stacked device structure. Stacked device structure 10A includes a device stack having an upper device 12U vertically stacked over a lower device 12L, a substrate 14, and an isolation structure 16A between and separating device 12U and device 12L. Isolation structure 16A includes isolation structures 17A and isolation structures 18. In some embodiments, device 12U and device 12L are stacked back-to-front. For example, a backside of device 12U may be bonded and/or attached to a frontside of device 12L by isolation structure 16A, and isolation structure 16A may be referred to as a bonding layer and/or bonding structure. FIG. 1A has been simplified for the sake of clarity to better understand the inventive concepts of the present disclosure. Additional features may be added in stacked device structure 10A, and some of the features described below may be replaced, modified, or eliminated in other embodiments of stacked device structure 10A.

Device 12U and device 12L each include at least one electrically functional device, such as an upper transistor 20U and a lower transistor 20L, respectively. Stacked device structure 10A thus includes at least one transistor stack having a top transistor (e.g., transistor 20U) and a bottom transistor (e.g., transistor 20L), which may be separated and/or electrically isolated from one another by isolation structure 16A. In some embodiments, transistor 20L and transistor 20U are transistors of opposite conductivity type. For example, transistor 20L is a p-type transistor, and transistor 20U is an n-type transistor, or vice versa. In such embodiments, transistor 20L and transistor 20U may form a CFET. In some embodiments, transistor 20L and transistor 20U are transistors of a same conductivity type. For example, transistor 20L and transistor 20U may both be n-type transistors or both p-type transistors.

Device 12U includes various features and/or components, such as semiconductor layers 26U, semiconductor layers 26M, gate spacers 44, inner spacers 54, source/drains 62U, a contact etch stop layer (CESL) 70U, an interlayer dielectric (ILD) layer 72U, gate dielectrics 78U and gate electrodes 80U (which collectively form gate stacks 90U), and hard masks 92. Device 12L also includes various features and/or components, such as a protrusion 14′ (which may be an extension of substrate 14), semiconductor layers 26L, semiconductor layers 26M, substrate isolation structures, inner spacers 54, source/drains 62L, a CESL 70L, an ILD layer 72L, and gate dielectrics 78L and gate electrodes 80L (which collectively form gate stacks 90L). A respective gate stack 90U and a respective gate stack 90L may collectively be referred to as a gate 90 of stacked device structure 10A. In some embodiments, gate stacks 90U are separated from gate stacks 90L by isolation structures 17A and semiconductor layers 26M, and source/drains 62U are separated from source/drains 62L by isolation structures 18.

In the depicted embodiment, transistor 20L is a GAA transistor. For example, transistor 20L has two channels provided by semiconductor layers 26L (also referred to as channel layers or channels), which are suspended over substrate 14 and extend between respective source/drains (e.g., source/drains 62L). In some embodiments, transistor 20L includes more or less channels (and thus more or less semiconductor layers 26L). Transistor 20L further has gate stack 90L disposed over and engaging its semiconductor layers 26L. Gate stack 90L is disposed between source/drains 62L, and inner spacers 54 are disposed between gate stack 90L and source/drains 62L. Along a gate widthwise direction (e.g., in an X-Z plane), gate stack 90L is disposed over top semiconductor layer 26L, between semiconductor layers 26L, and between bottom semiconductor layer 26L and substrate 14. Along a gate lengthwise direction (e.g., in a Y-Z plane), gate stack 90L wraps around semiconductor layers 26L. During operation of the GAA transistor, current can flow through semiconductor layers 26L and between source/drains 62L. Semiconductor layers 26M (also referred to as dummy channel layers or dummy channels) are suspended over substrate 14 and extend between respective isolation structures 18, and isolation structures 17A are disposed between semiconductor layers 26M of device 12L/transistor 20L and semiconductor layers 26M of device 12U/transistor 20U.

In the depicted embodiment, transistor 20U is also a GAA transistor. For example, transistor 20U has two channels provided by semiconductor layers 26U (also referred to as channel layers or channels), which are suspended over substrate 14 and extend between respective source/drains (e.g., source/drains 62U). In some embodiments, transistor 20U includes more or less channels/semiconductor layers 26U. Transistor 20U further has gate stack 90U disposed over and engaging its semiconductor layers 26U. Gate stack 90U is disposed between source/drains 62U, gate stack 90U is disposed between respective gate spacers 44, inner spacers 54 are disposed between gate stack 90U and source/drains 62U, and hard mask 92 is disposed over gate stack 90U. Along a gate widthwise direction, gate stack 90U is over top semiconductor layer 26U, between semiconductor layers 26U, and between bottom semiconductor layer 26U and semiconductor layer 26M. Along a gate lengthwise direction, gate stack 90U wraps around semiconductor layers 26U. During operation of the GAA transistor, current can flow through semiconductor layers 26U and between source/drains 62U.

Fabricating stacked device structure 10A monolithically provides isolation structure 16A with isolation structures 17A and isolation structures 18 between channel regions and source/drain regions, respectively, of device 12L and device 12U. For example, a respective isolation structure 17A is between a channel region of transistor 20L and a channel region of transistor 20U (e.g., between channels and/or gates thereof), and isolation structures 18 are between source/drain regions of transistor 20L and source/drain regions of transistor 20U. In the depicted embodiment, a respective isolation structure 17A is between semiconductor layer 26M of transistor 20L and semiconductor layer 26M of transistor 20U, and respective isolation structures 18 are between source/drains 62L and source/drains 62U. Accordingly, isolation structures 17A may function as channel isolation structures and/or gate isolation structures, and isolation structures 18 may function as source/drain isolation structures.

Isolation structures 17A and isolation structures 18 may include a single layer or multiple layers. Isolation structures 17A and isolation structures 18 include a dielectric material, which may include silicon, oxygen, carbon, nitrogen, other suitable dielectric constituent, or combinations thereof (e.g., silicon oxide, silicon nitride, silicon oxynitride, silicon carbide, silicon carbonitride, silicon oxycarbide, silicon oxycarbonitride, or combinations thereof). Isolation structures 17A and isolation structures 18 may include the same or different materials and/or configurations. In the depicted embodiment, a thickness of isolation structures 17A is less than a thickness of isolation structures 18, and a configuration of isolation structures 17A is different than a configuration of isolation structures 18. In some embodiments, isolation structures 18 are formed by respective portions of CESL 70L and ILD layer 72L.

Substrate 14, semiconductor layers 26U, semiconductor layers 26M, and semiconductor layers 26L include an elementary semiconductor, such as silicon and/or germanium; a compound semiconductor, such as silicon carbide, gallium arsenide, gallium phosphide, indium phosphide, indium arsenide, indium antimonide, or combinations thereof; an alloy semiconductor, such as SiGe, GaAsP, AlInAs, AlGaAs, GaInAs, GaInP, GaInAsP, or combinations thereof; or combinations thereof. In the depicted embodiment, substrate 14 semiconductor layers 26U, semiconductor layers 26M, and semiconductor layers 26L include silicon. In some embodiments, semiconductor layers 26U and semiconductor layers 26L include different semiconductor materials, such as silicon and silicon germanium, respectively, or vice versa. In some embodiments, substrate 14 is a semiconductor-on-insulator substrate, such as a silicon-on-insulator substrate, a silicon germanium-on-insulator substrate, or a germanium-on-insulator substrate. Substrate 14 and/or protrusion 14′ may include various doped regions, such as p-wells and n-wells. The n-wells are doped with n-type dopants, such as phosphorus, arsenic, other n-type dopant, or combinations thereof. The p-wells are doped with p-type dopants, such as boron, indium, other p-type dopant, or combinations thereof.

Gate spacers 44 are disposed along sidewalls of upper portions of gate stacks 90U, inner spacers 54 are disposed under gate spacers 44 along sidewalls of gate stacks 90U and/or gate stacks 90L, and fin/protrusion spacers may be disposed along sidewalls of protrusions 14′. Inner spacers 54 are between semiconductor layers 26 and between bottom semiconductor layers 26 and protrusions 14′. Gate spacers 44, inner spacers 54, and fin spacers include a dielectric material, which may include silicon, oxygen, carbon, nitrogen, other suitable dielectric constituent, or combinations thereof (e.g., silicon oxide, silicon nitride, silicon oxynitride, silicon carbide, silicon carbonitride, silicon oxycarbide, silicon oxycarbonitride, or combinations thereof). Gate spacers 44, inner spacers 44, and fin spacers may include different materials and/or different configurations (e.g., different numbers of layers). In some embodiments, gate spacers 44, inner spacers 54, fin spacers, or combinations thereof have a multilayer structure. In some embodiments, gate spacers 44 and/or fin spacers include more than one set of spacers, such as seal spacers, offset spacers, sacrificial spacers, dummy spacers, main spacers, or combinations thereof. The various sets of spacers may have different compositions.

Gate 90 is disposed between source/drain stacks. Each source/drain stack includes a respective source/drain 62U, a respective source/drain 62L, and a respective isolation structure 18 disposed therebetween. Source/drains 62L and source/drains 62U include semiconductor material, and source/drains 62L and source/drains 62U may be doped with n-type dopants and/or p-type dopants. In some embodiments, source/drains 62L and source/drains 62U are formed of epitaxially grown/deposited semiconductor material(s), and source/drains 62L and source/drains 62U may be referred to as epitaxial source/drains. Source/drains 62L and source/drains 62U may have the same or different compositions and/or materials depending on configurations of their respective transistors. In some embodiments (e.g., when forming portions of n-type transistors), source/drains 62L and/or source/drains 62U include silicon doped with carbon, phosphorous, arsenic, other n-type dopant, or combinations thereof (e.g., Si: C epitaxial source/drains, Si: P epitaxial source/drains, or Si: C: P epitaxial source/drains). In some embodiments (e.g., when forming portions of p-type transistors), source/drains 62L and/or source/drains 62U include silicon germanium or germanium doped with boron, other p-type dopant, or combinations thereof (e.g., Si: Ge: B epitaxial source/drains). In some embodiments, source/drains 62L include silicon germanium doped with boron, and source/drains 62U include silicon doped with phosphorous, or vice versa. In some embodiments, doped regions, such as heavily doped source/drain (HDD) regions, lightly doped source/drain (LDD) regions, other doped regions, or combinations thereof, are disposed in source/drains 62L and/or source/drains 62U. In some embodiments, source/drains 62L and/or source/drains 62U include multiple semiconductor layer, and the semiconductor layers may include the same or different materials, compositions, dopant type, dopant concentrations, thicknesses, etc. In some embodiments, source/drains 62L and/or source/drains 62U include materials and/or dopants that achieve desired tensile stress and/or compressive stress in adjacent channel regions (e.g., formed by semiconductor layers 26U and semiconductor layers 26L). As used herein, source/drain region, source/drain, epitaxial source/drain, epitaxial source/drain feature, etc. may refer to a source of a device (e.g., transistor 20U and/or transistor 20L), a drain of a device (e.g., transistor 20U and/or transistor 20L), or a source and/or a drain of multiple devices.

ILD layer 72U and ILD layer 72L include a dielectric material, such as silicon oxide, carbon doped silicon oxide, silicon nitride, silicon oxynitride, tetraethyl orthosilicate (TEOS)-formed oxide, boron silicate glass (BSG), phosphosilicate glass (PSG), borophosphosilicate glass (BPSG), fluorosilicate glass (FSG), xerogel, aerogel, amorphous fluorinated carbon, parylene, benzocyclobutene-based (BCB) material, polyimide, other dielectric material, or combinations thereof. In some embodiments, ILD layer 72U and/or ILD layer 72L includes a dielectric material having a dielectric constant that is less than a dielectric constant of silicon dioxide. CESL 70L and CESL 70U include a material different than a material of ILD layer 72L and ILD layer 72U, respectively. For example, where ILD layer 72U and ILD layer 72L include a low-k dielectric material that includes silicon and oxygen, CESL 70U and CESL 70L may include silicon and nitrogen and/or carbon. ILD layer 72U, ILD layer 72L CESL 70L, CESL 70U, or combinations thereof may have a multilayer structure.

Gate dielectrics 78U and gate dielectrics 78L each include at least one dielectric gate layer. Gate dielectrics 78U and gate dielectrics 78L may have the same or different compositions, materials, layers, configurations, or combinations thereof. In some embodiments, gate dielectrics 78U and/or gate dielectrics 78L include an interfacial layer that includes a dielectric material, such as SiO₂, SiGeOₓ, HfSiO, SiON, other dielectric material, or combinations thereof. In some embodiments, gate dielectrics 78U and/or gate dielectrics 78L include a high-k dielectric layer, which includes a dielectric material having a dielectric constant that is greater than a dielectric constant of silicon dioxide (k≈3.9), such as HfO₂, HfSiO, HfSiO₄, HfSiON, HfLaO, HfTaO, HfTiO, HfZrO, HfAlOₓ, ZrO, ZrO₂, ZrSiO₂, AlO, AlSiO, Al₂O₃, TIO, TiO₂, LaO, LaSiO, LaO₃, La₂O₃, Ta₂O₃, Ta₂O₅, Y₂O₃, SrTiO₃, BaZrO, BaTiO₃ (BTO), (Ba,Sr)TiO₃ (BST), Si₃N₄, HfO₂-Al₂O₃, other high-k dielectric material, or combinations thereof. For example, gate dielectrics 78U and/or gate dielectrics 78L may include a hafnium-based oxide (e.g., HfO₂) layer and/or a zirconium-based oxide (e.g., ZrO₂) layer. The interfacial layer and/or the high-k dielectric layer may have a multilayer structure.

Gate electrodes 80U and gate electrodes 80L are disposed over gate dielectrics 78U and gate dielectrics 78L, respectively. Gate electrodes 80U and gate electrodes 80L may have the same or different compositions, materials, layers, configurations, or combinations thereof. Gate electrodes 80U and gate electrodes 80L each include at least one electrically conductive gate layer formed of an electrically conductive material, such as Al, Cu, Ti, Ta, W, Mo, Co, TaN, NiSi, CoSi, TiN, WN, TiAl, TiAlN, TaCN, TaC, TaSiN, other electrically conductive material, or combinations thereof. In some embodiments, the electrically conductive gate layer includes a work function layer tuned to have a desired work function (e.g., an n-type work function or a p-type work function). The work function layer includes work function metal(s) and/or alloys thereof, such as Ti, Ta, Al, Ag, Mn, Zr, W, Ru, Mo, TiC, TiAl, TiAlC, TiAlSiC, TaC, TaCN, TaSiN, TiSiN, TiN, TaN, TaSN, WN, WCN, ZrSi₂, MoSi₂, TaSi₂, NiSi₂, TaAl, TaAlC, TaSiAlC, TiAlN, or combinations thereof. In some embodiments, the electrically conductive gate layer includes a bulk layer over the gate dielectric and/or the work function layer. The bulk layer may include Al, W, Cu, Ti, Ta, TiN, TaN, polysilicon, other suitable metal(s) and/or alloys thereof, or combinations thereof. In some embodiments, the electrically conductive gate layer includes a barrier layer over the work function layer and/or the gate dielectric. The barrier layer includes a material that may prevent diffusion and/or reaction of constituents between adjacent layers and/or promote adhesion between adjacent layers, such as between the work function layer and the bulk layer. In some embodiments, the barrier layer includes metal and nitrogen, such as titanium nitride, tantalum nitride, tungsten nitride, titanium silicon nitride, tantalum silicon nitride, other suitable metal nitride, or combinations thereof.

Hard masks 92 include a material that is different than ILD layer 72U and/or subsequently formed ILD layers to achieve etch selectivity during subsequent etching processes. In some embodiments, hard masks 92 include silicon and nitrogen and/or carbon, such as silicon nitride, silicon oxynitride, silicon carbide, silicon oxycarbide, silicon carbonitride, silicon oxycarbonitride, other silicon nitride, other silicon carbide, or combinations thereof. In some embodiments, hard masks 92 include metal and oxygen and/or nitrogen, such as aluminum oxide (e.g., AlO or Al₂O₃), aluminum nitride (e.g., AlN), aluminum oxynitride (e.g., AlON), zirconium oxide, zirconium nitride, hafnium oxide (e.g., HfO or HFO₂), zirconium aluminum oxide (e.g., ZrAlO), other metal oxide, other metal nitride, or combinations thereof.

FIG. 1B is a cross-sectional view of a stacked device structure 10B, in portion or entirety, according to various aspects of the present disclosure. Stacked device structure 10B is fabricated sequentially, and thus may be referred to as a sequential stacked device structure. Since stacked device structure 10B is similar in many respects to stacked device structure 10A, similar features of stacked device structure 10B and stacked device structure 10A are identified by the same reference numerals for clarity and simplicity. For example, stacked device structure 10B includes device 12U vertically stacked over device 12L (i.e., a device stack disposed over substrate 14), and device 12L and device 12U each include at least one electrically functional device, such as transistor 20L and transistor 20U, respectively (each of which is configured as a GAA transistor). Device 12U includes semiconductor layers 26U, gate spacers 44U, inner spacers 54U, source/drains 62U, CESL 70U, ILD layer 72U, gate dielectrics 78U and gate electrodes 80U (which collectively form gate stacks 90U), and hard masks 92U. Device 12L includes protrusion 14′ (e.g., an extension of substrate 14), semiconductor layers 26L, substrate isolation structures, gate spacers 44L, inner spacers 54L, source/drains 62L, CESL 70L, ILD layer 72L, gate dielectrics 78L and gate electrodes 80L (which collectively form gate stacks 90L), and hard masks 92L. FIG. 1B has been simplified for the sake of clarity to better understand the inventive concepts of the present disclosure. Additional features may be added in stacked device structure 10B, and some of the features described below may be replaced, modified, or eliminated in other embodiments of stacked device structure 10B.

Stacked device structure 10B includes an isolation structure 16B, instead of isolation structure 16A, between and separating device 12U and device 12L. In some embodiments, device 12U and device 12L are stacked back-to-front. For example, isolation structure 16B may bond and/or attach a backside of device 12U to a frontside of device 12L, and isolation structure 16B may be referred to as a bonding layer/structure. Because stacked device structure 10B is fabricated sequentially, device 12U and device 12L have respective gate spacers (e.g., gate spacers 44U and gate spacers 44L, both of which may be similar to gate spacers 44), device 12U and device 12L have respective inner spacers (e.g., inner spacers 54U and inner spacers 54L, both of which may be similar to inner spacers 44), and device 12U and device 12L have respective hard masks (e.g., hard masks 92U and hard mask 92L, both of which may be similar to hard masks 92). Further, isolation structure 16B is provided with an isolation structure 17B. Gate stacks 90U are separated from gate stacks 90L by isolation structure 17B, device 12U and/or device 12L may not include semiconductor layers 26M, and source/drains 62U are separated from source/drains 62L by isolation structure 17B. Isolation structure 17B is thus between channel regions and source/drain regions, respectively, of device 12L and device 12U, and isolation structure 17B may provide electrical isolation of both channels/gates and source/drains of stacked devices. For example, isolation structure 17B extends continuously, without interruption between channel regions and source/drain regions of transistor 20L and transistor 20U. Isolation structure 17B may include a single layer or multiple layers. Isolation structure 17B includes a dielectric material, which may include silicon, oxygen, carbon, nitrogen, other suitable dielectric constituent, or combinations thereof.

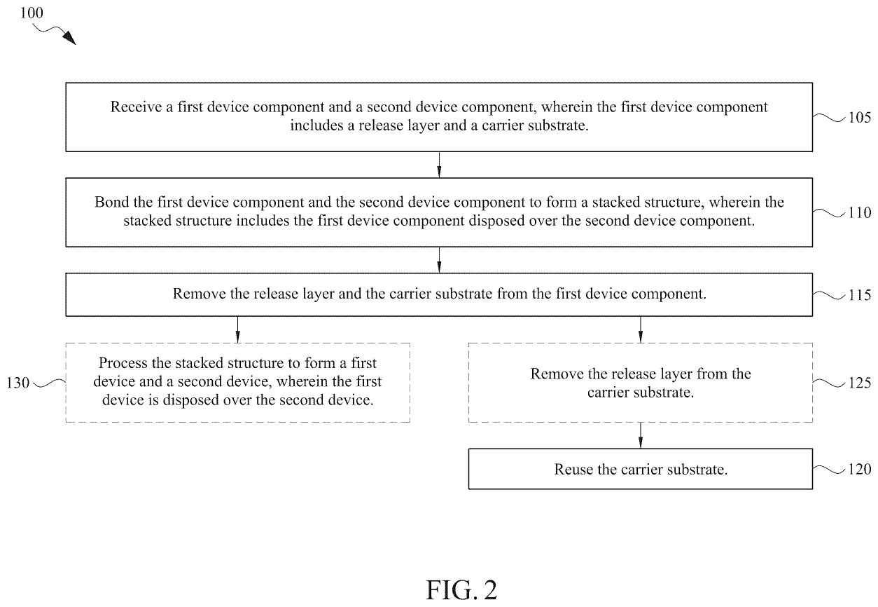

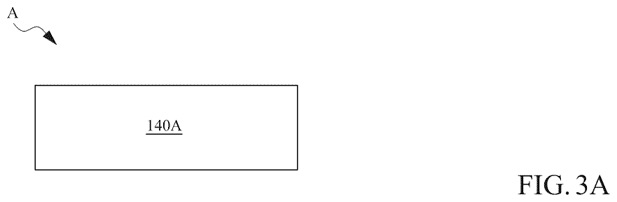

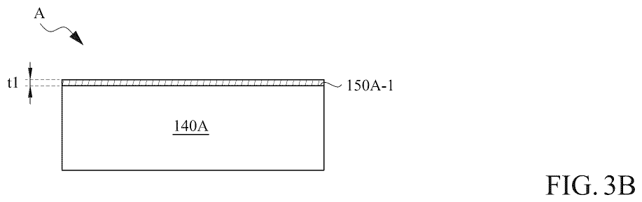

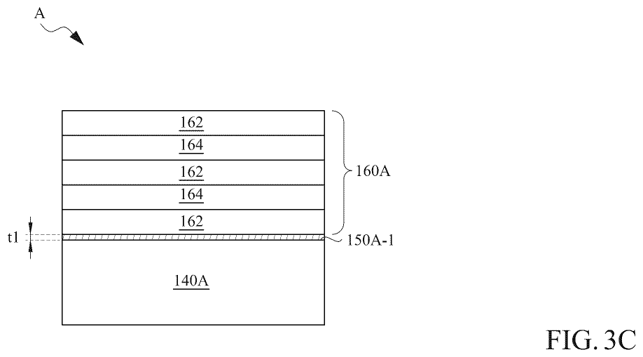

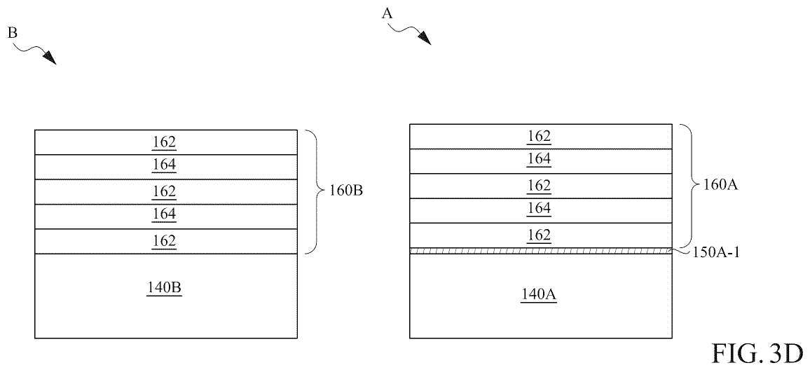

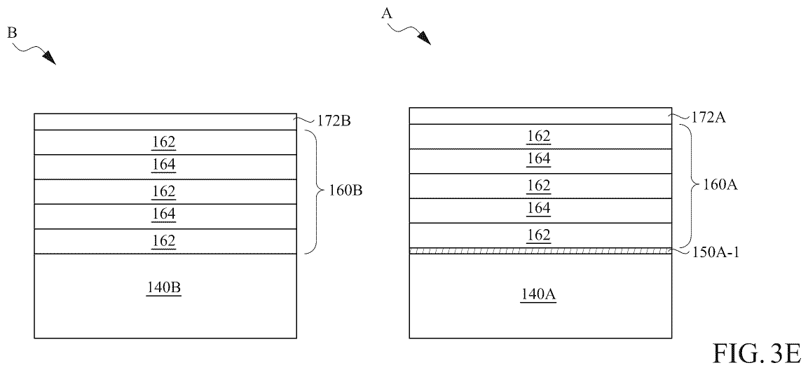

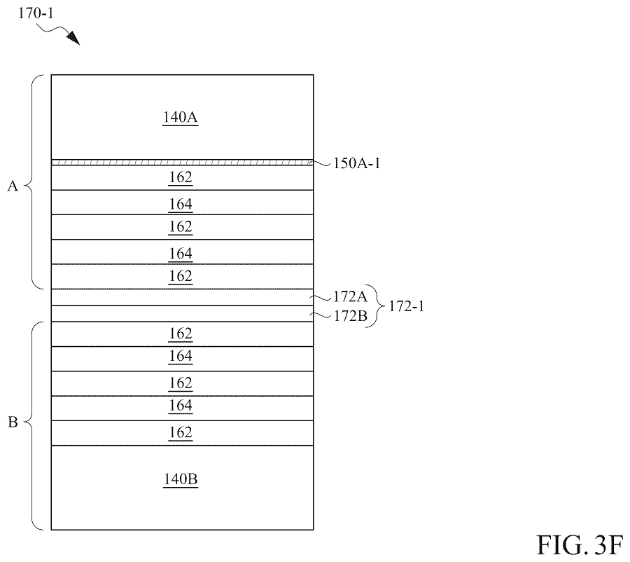

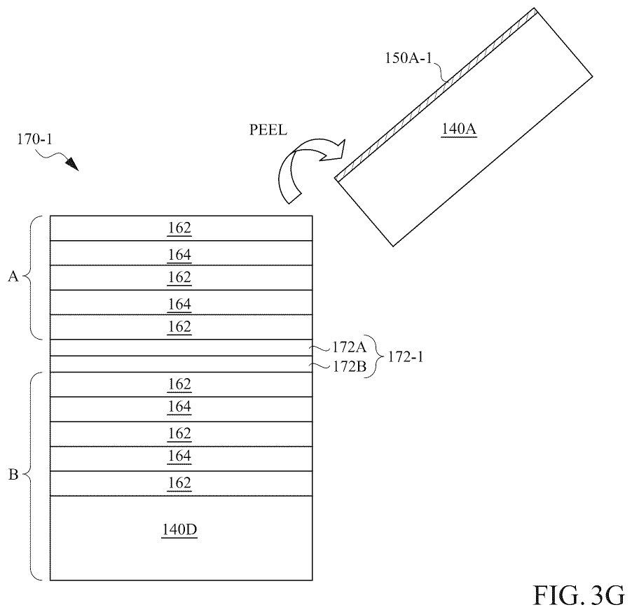

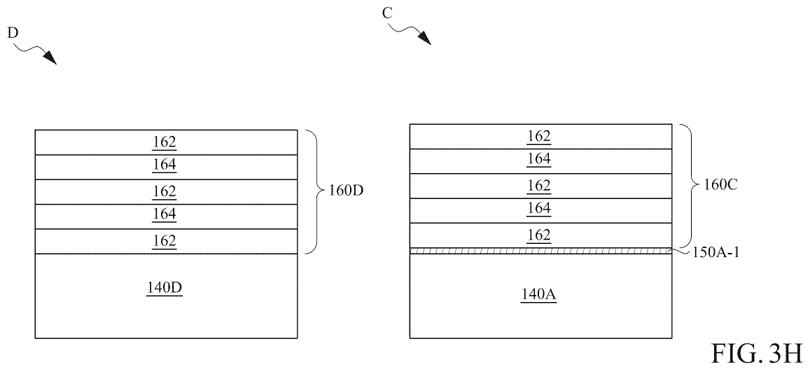

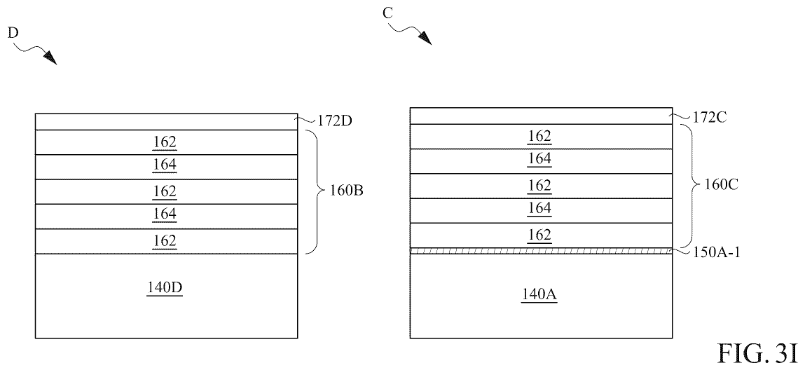

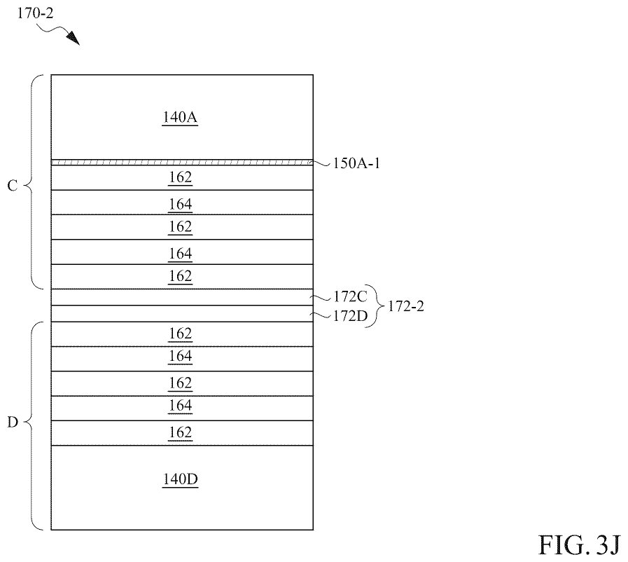

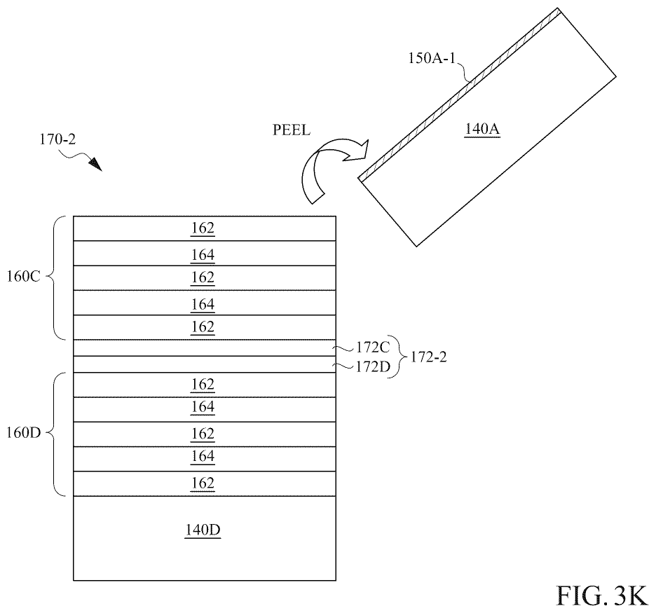

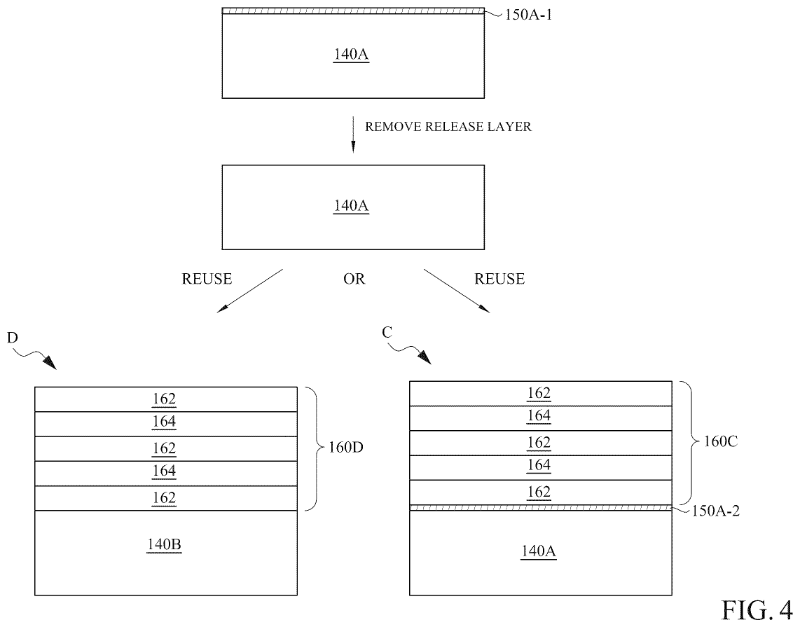

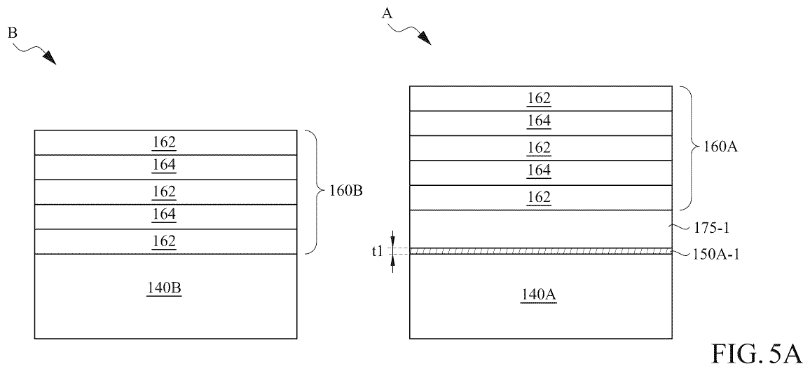

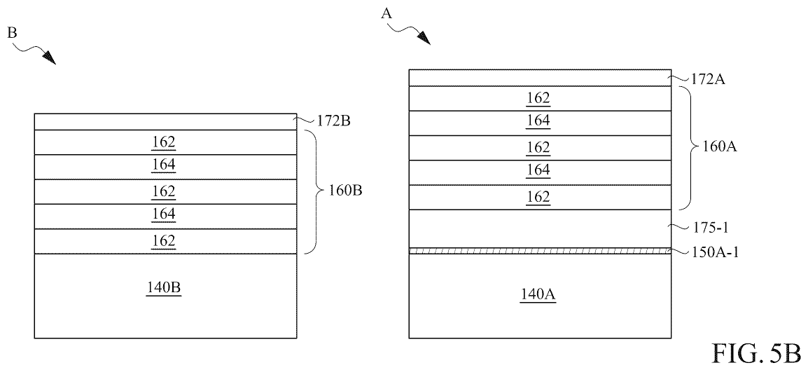

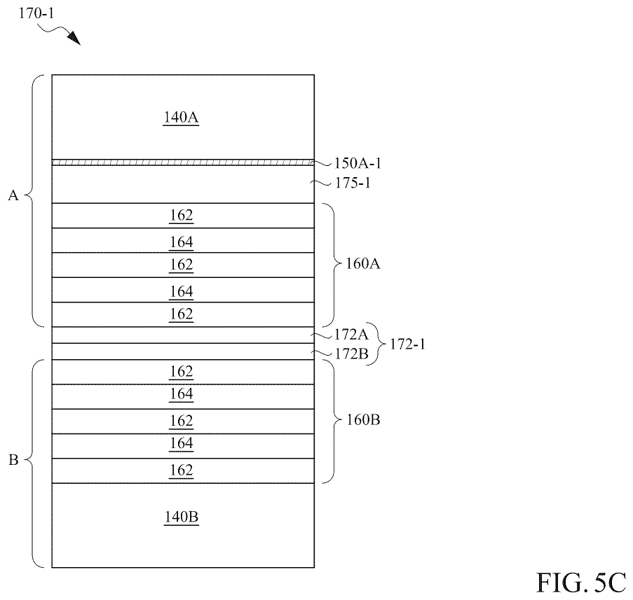

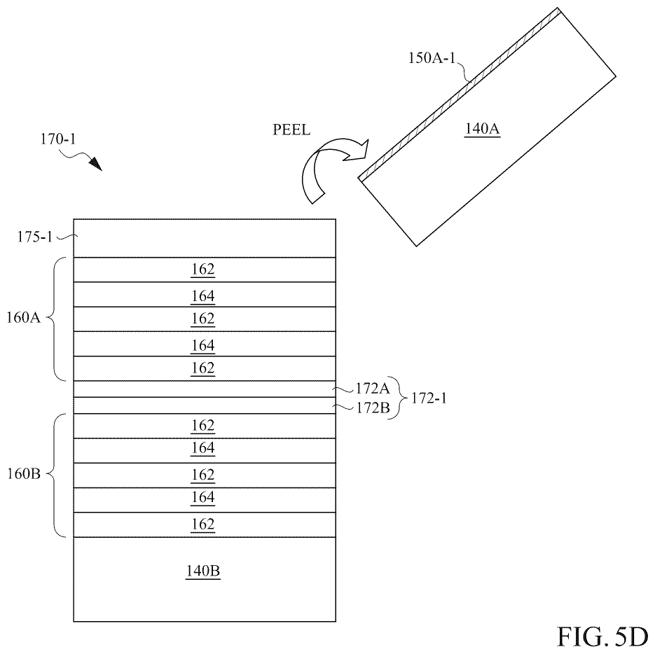

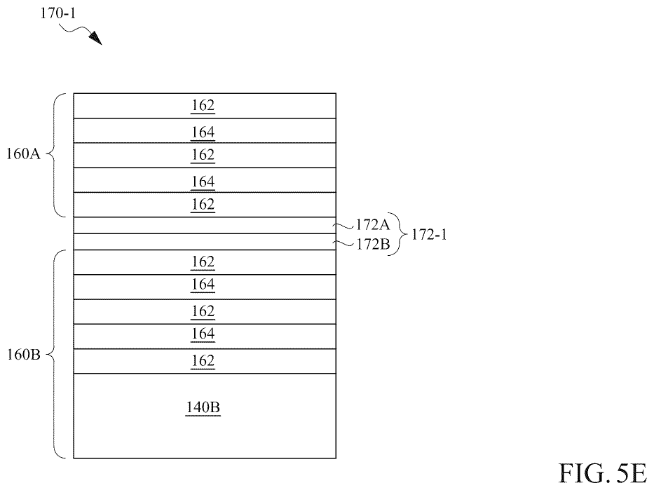

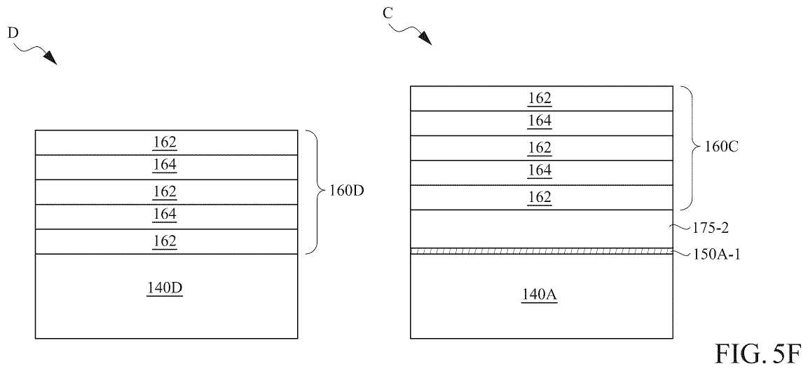

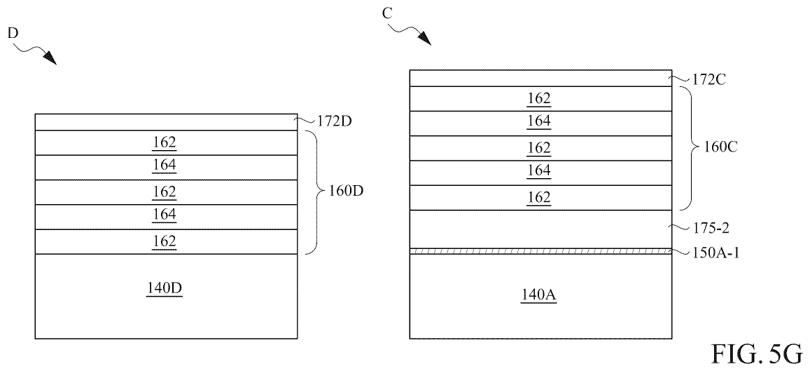

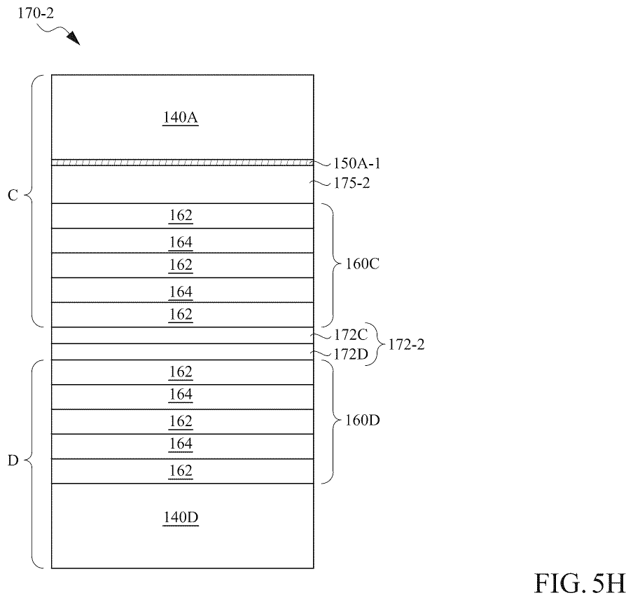

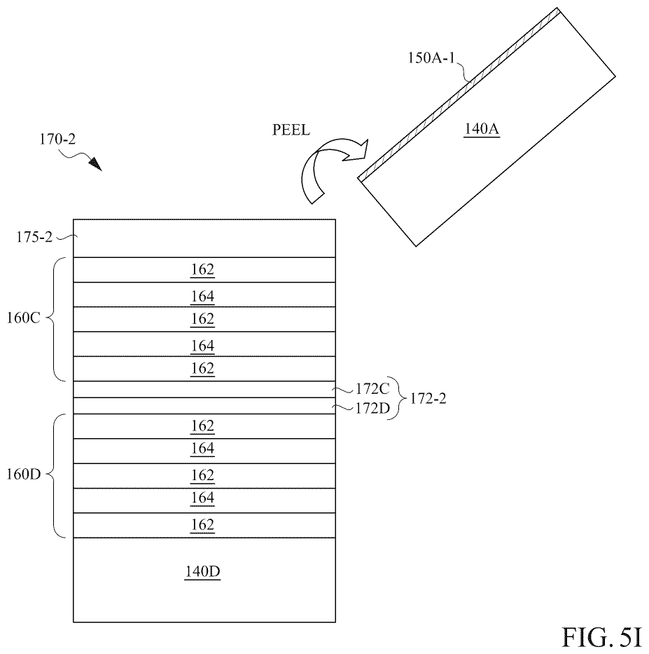

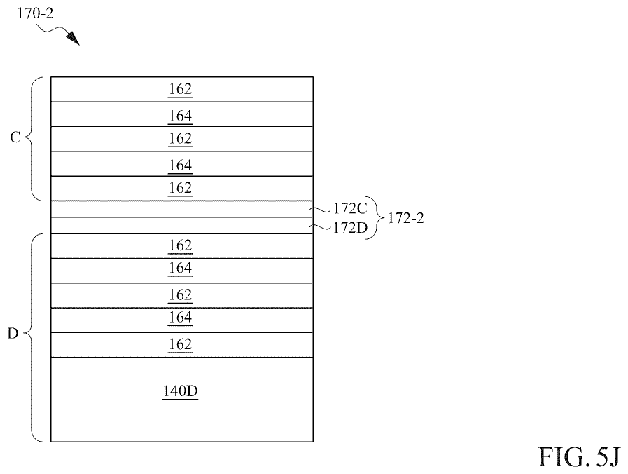

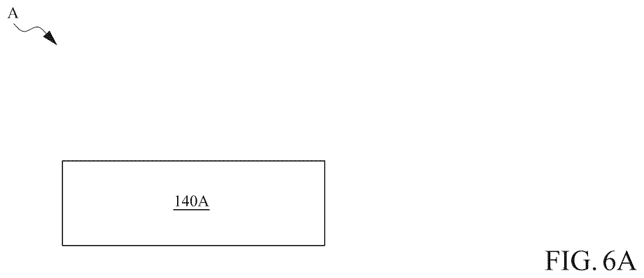

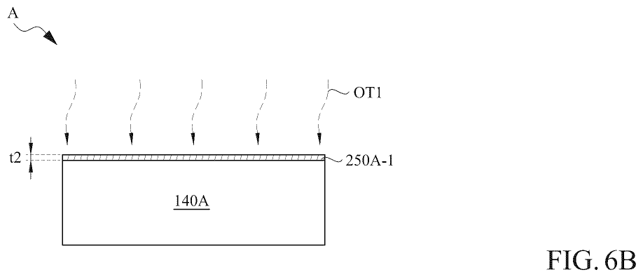

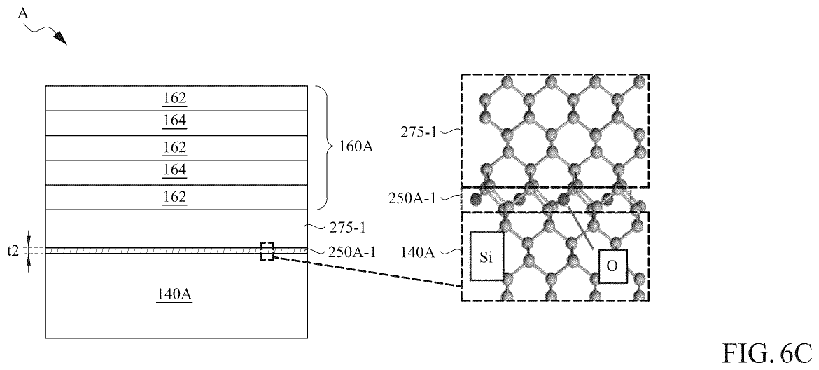

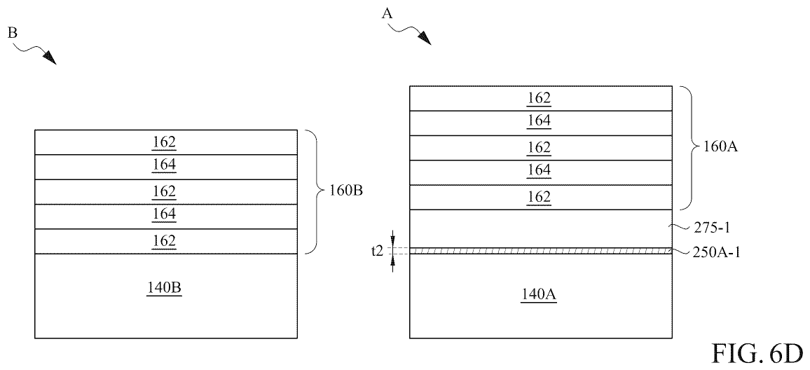

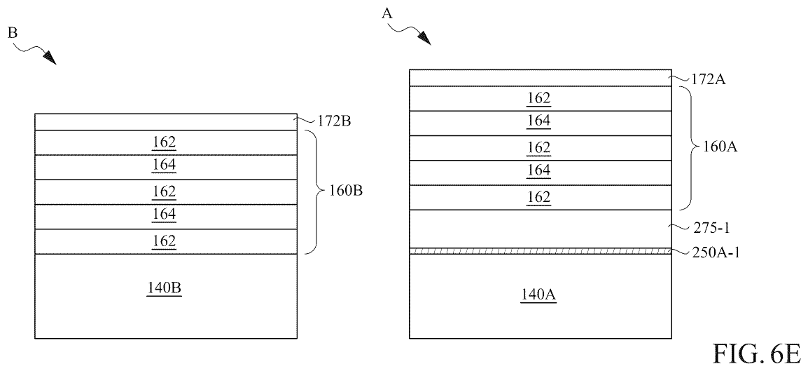

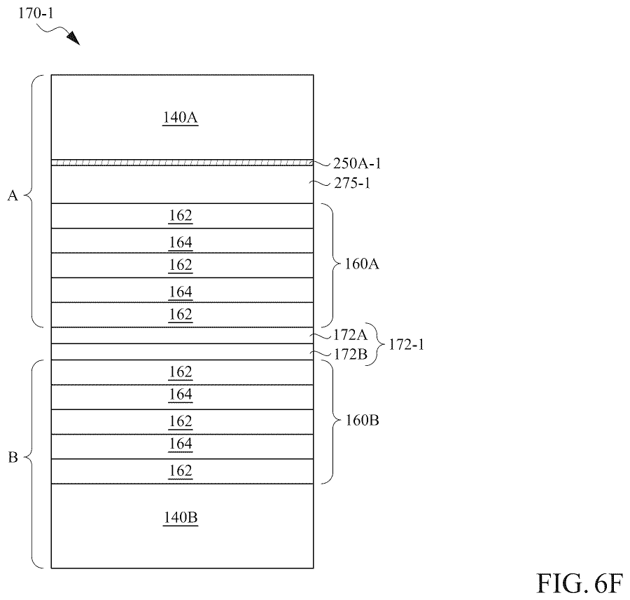

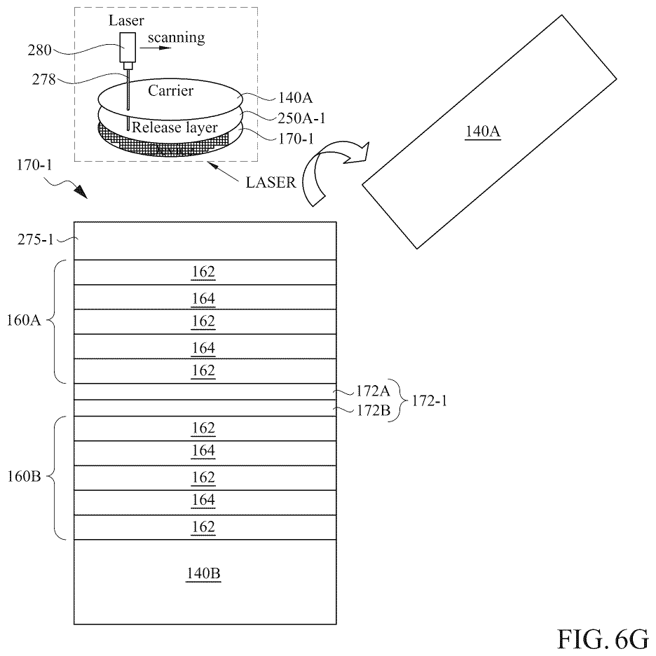

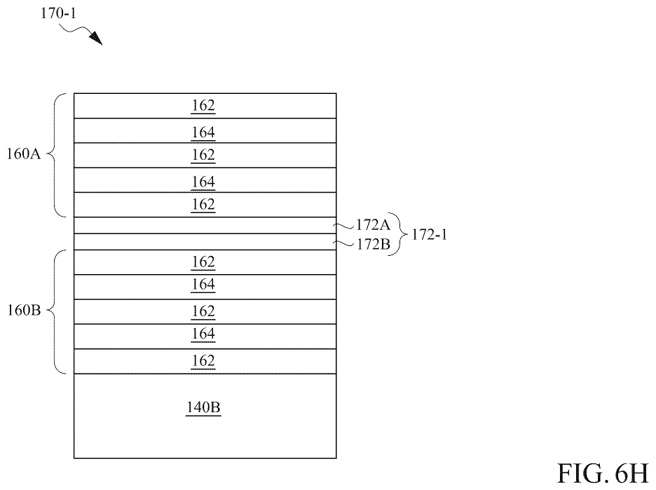

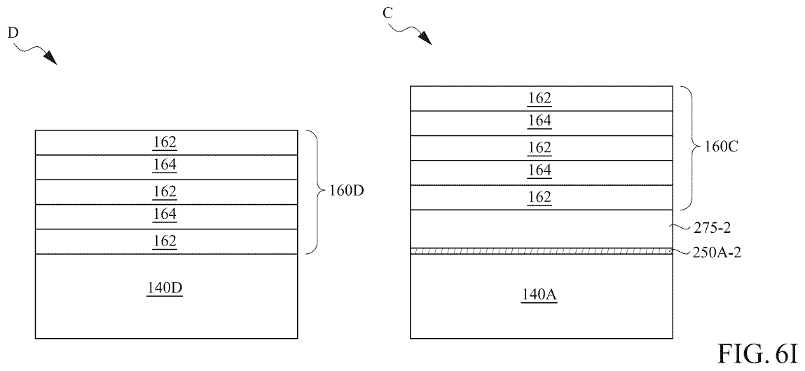

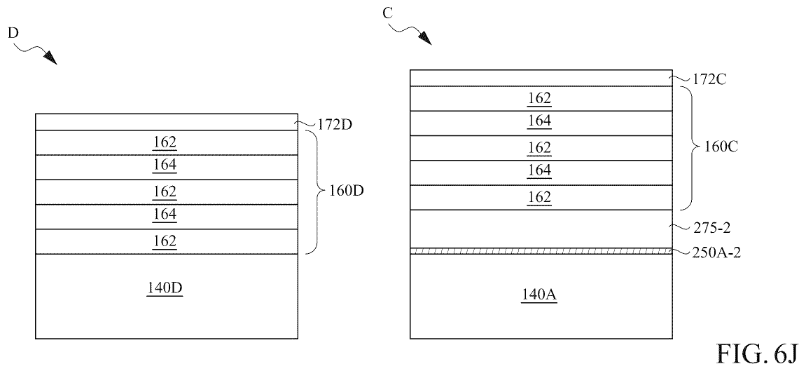

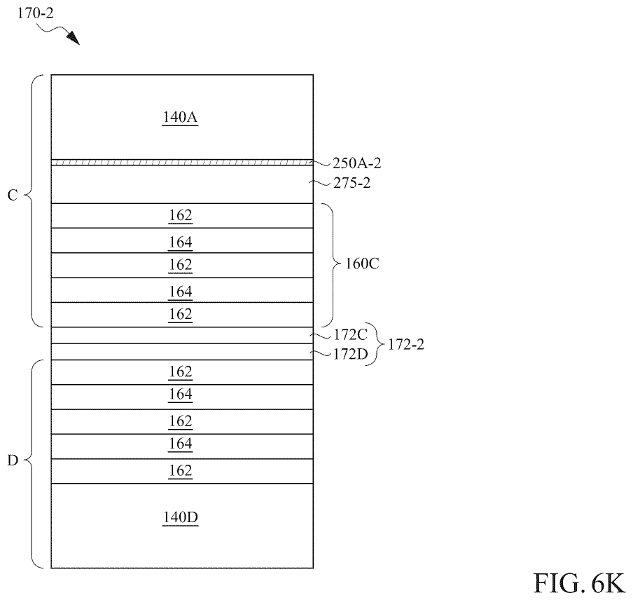

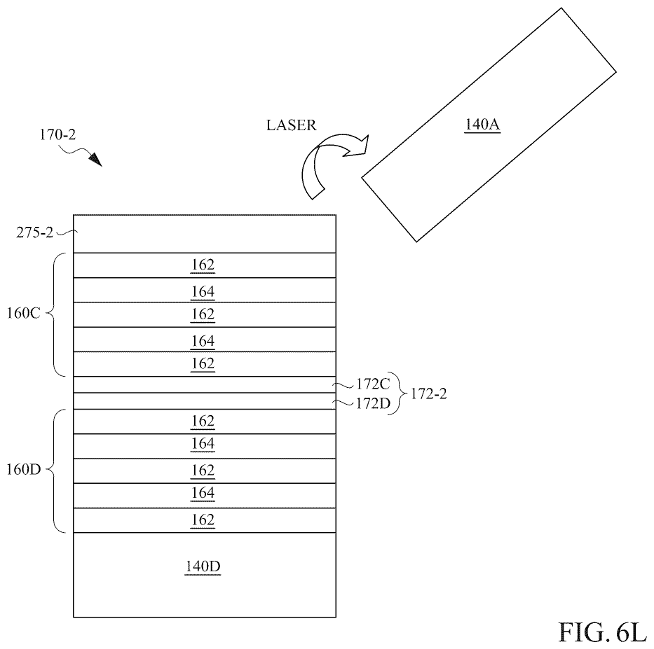

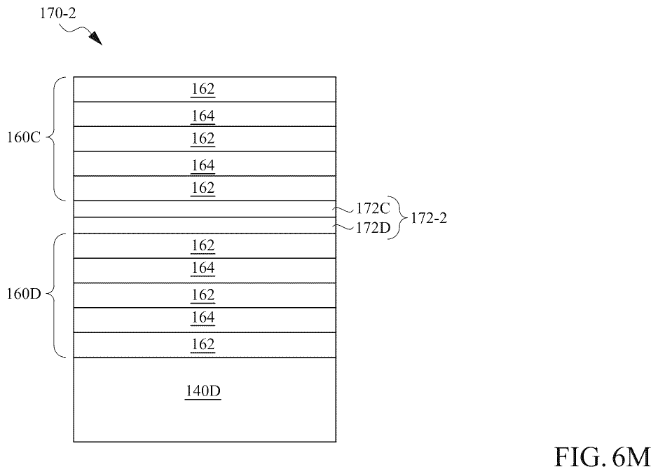

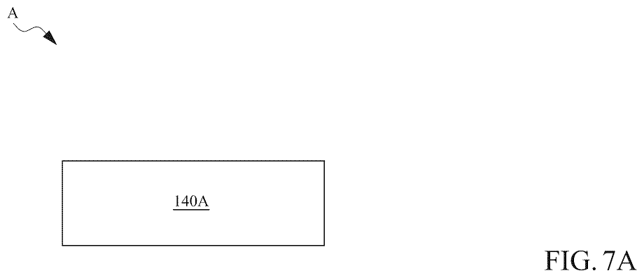

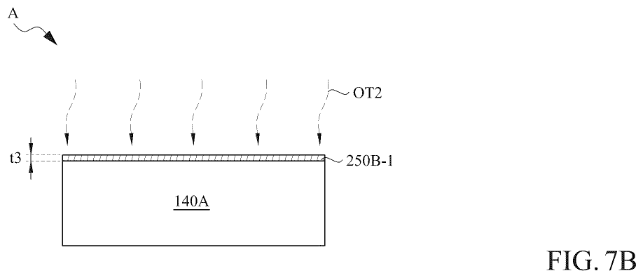

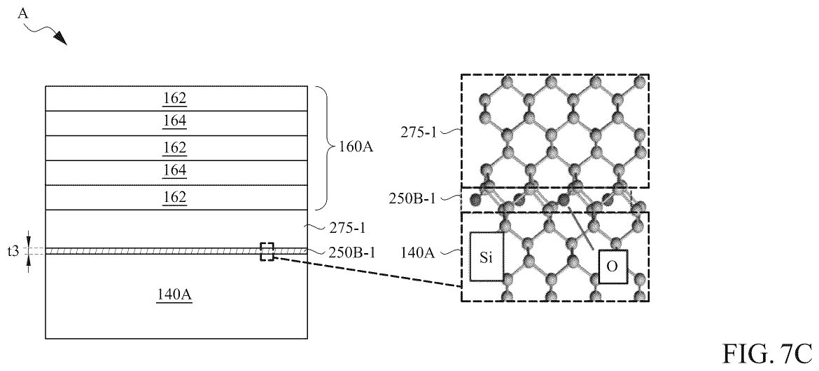

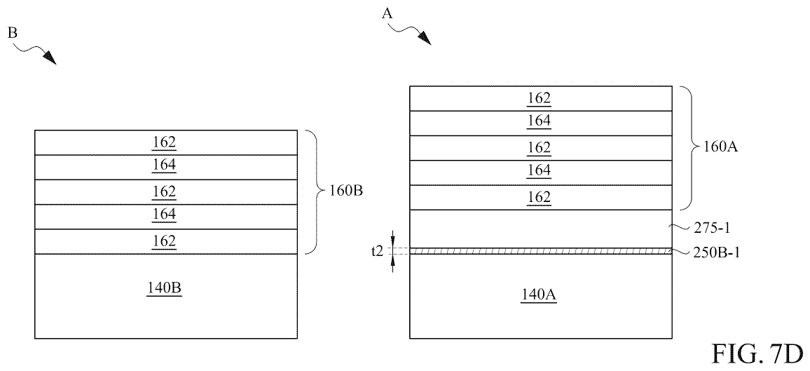

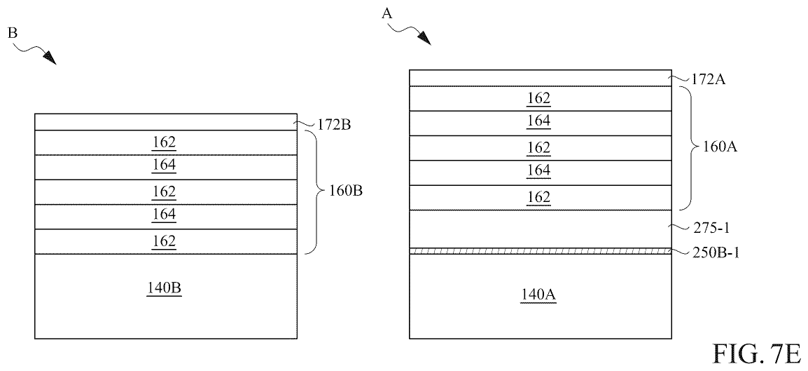

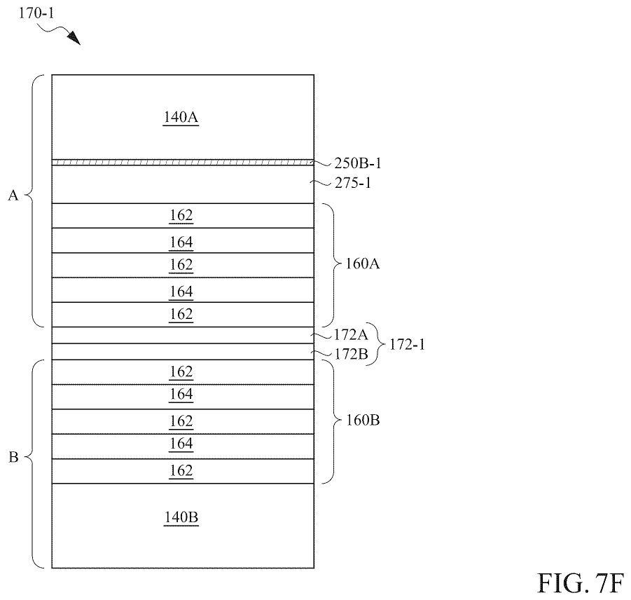

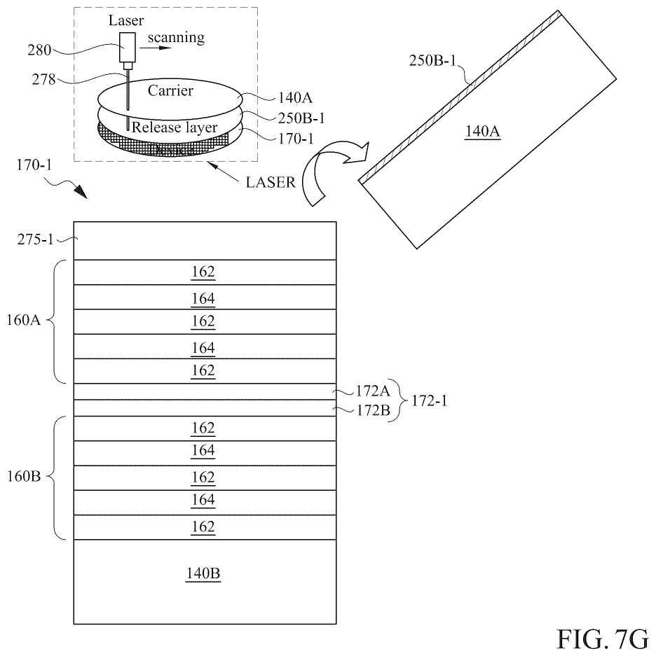

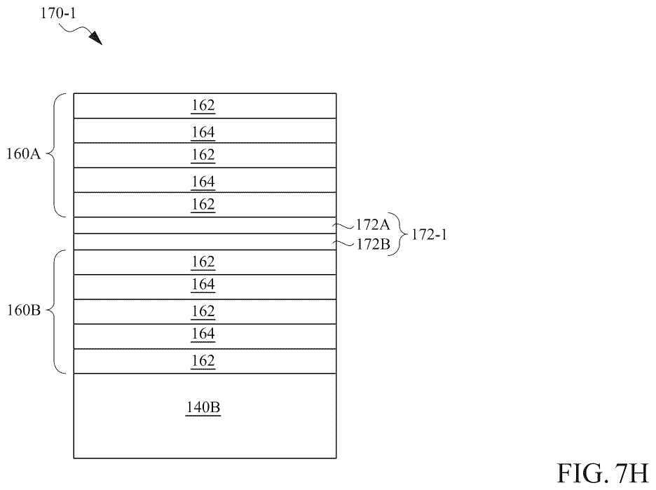

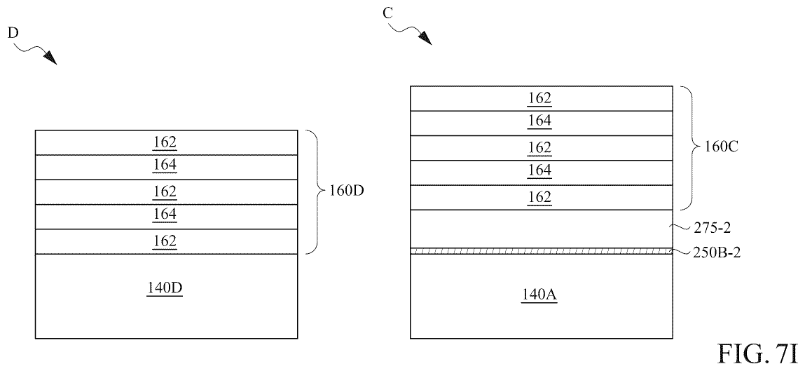

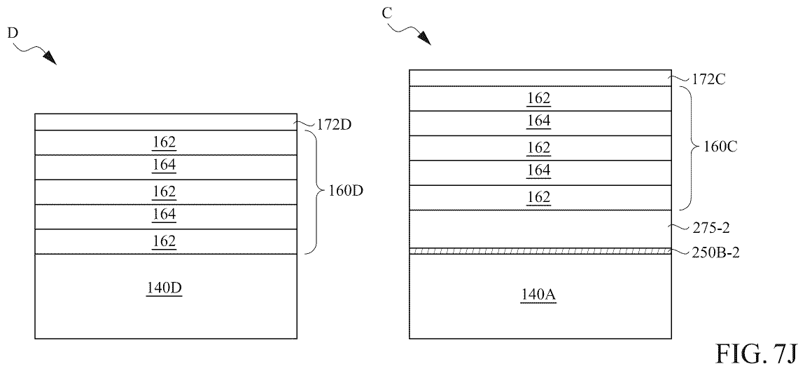

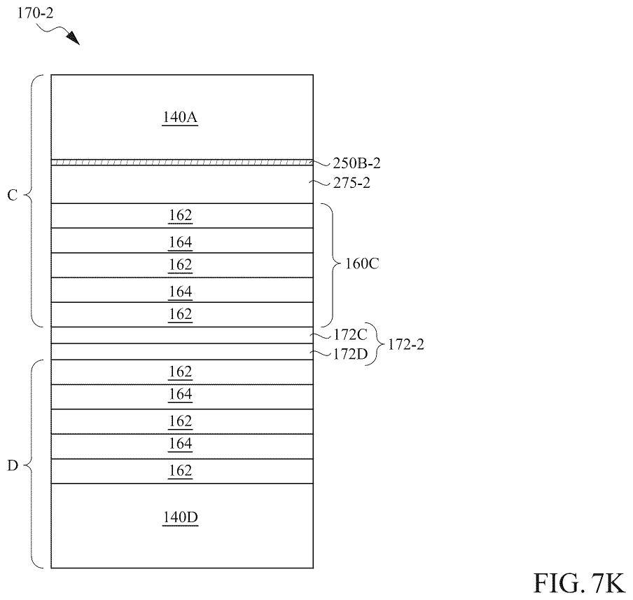

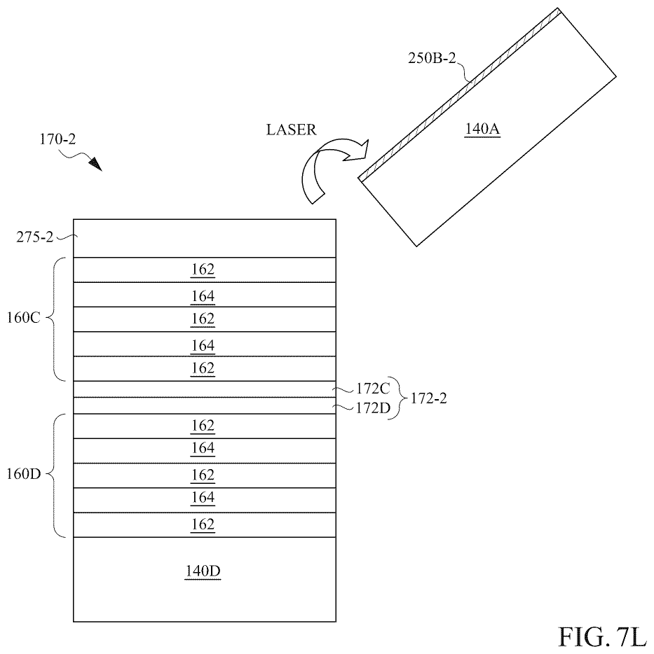

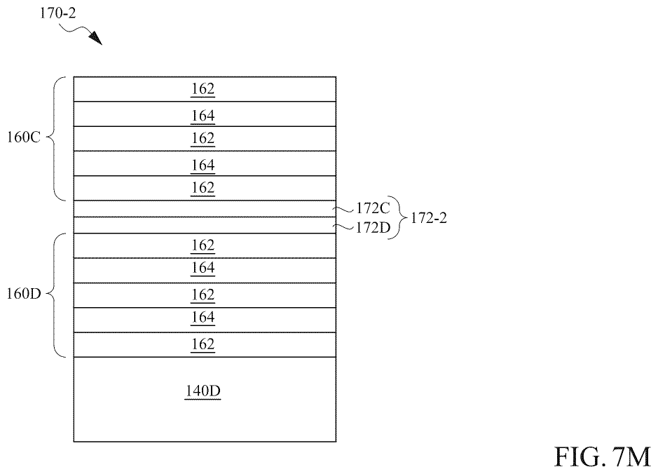

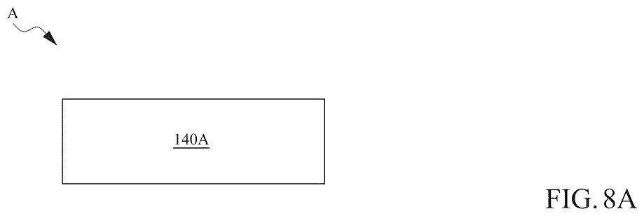

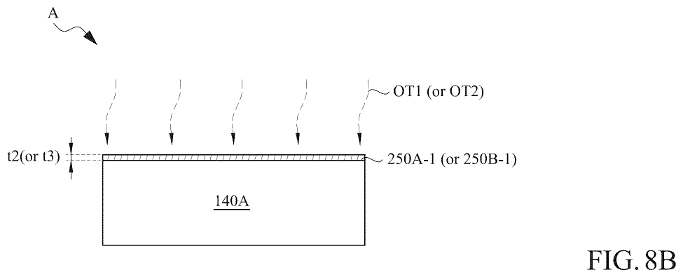

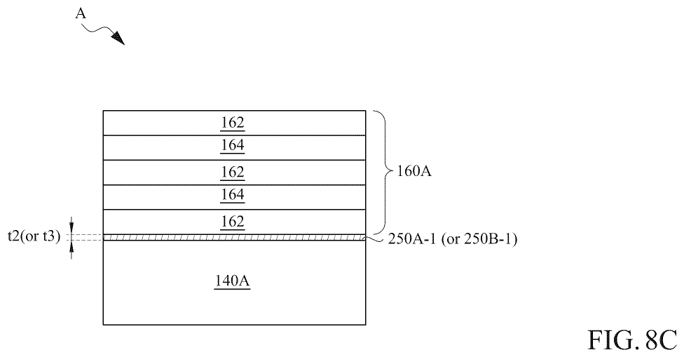

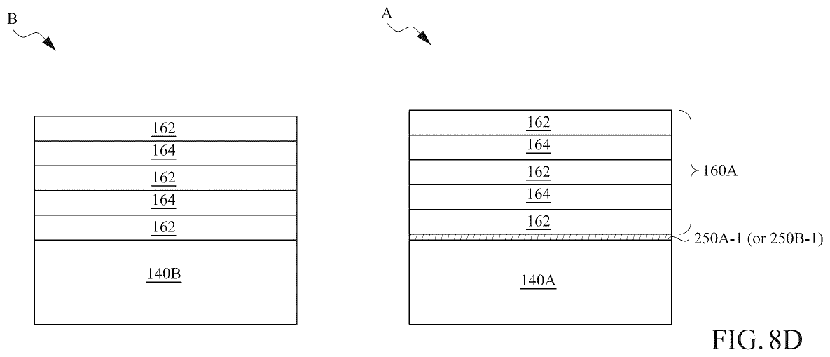

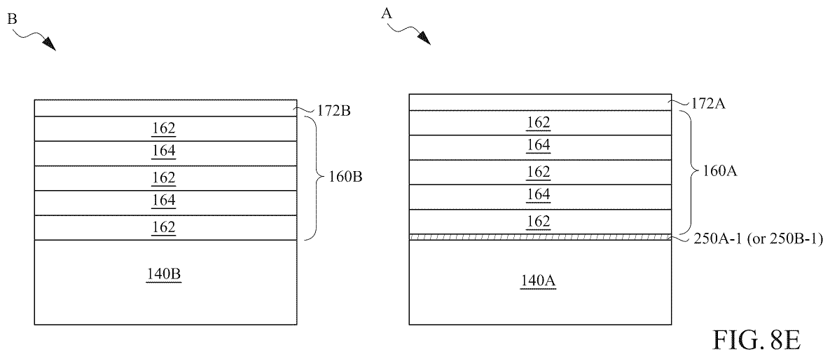

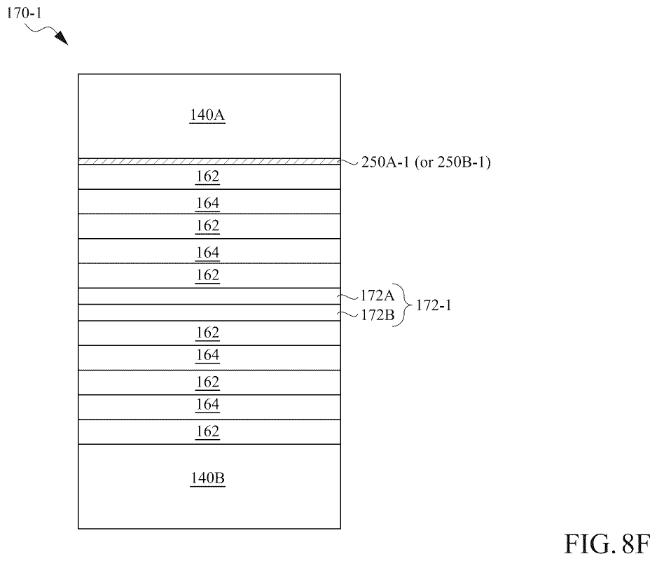

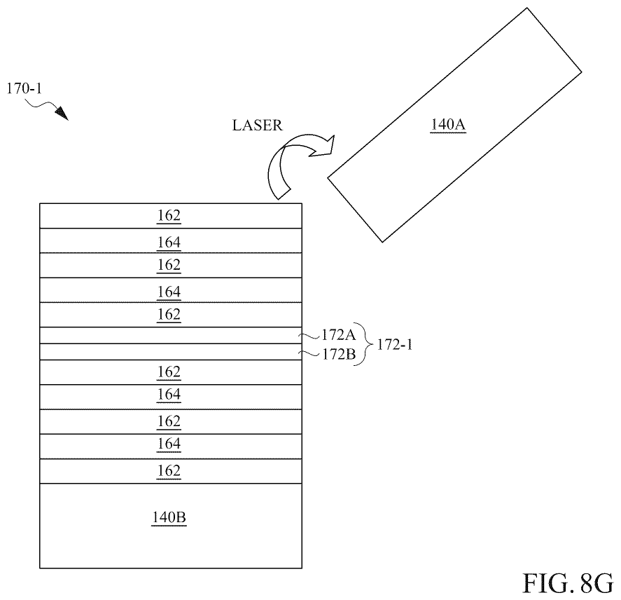

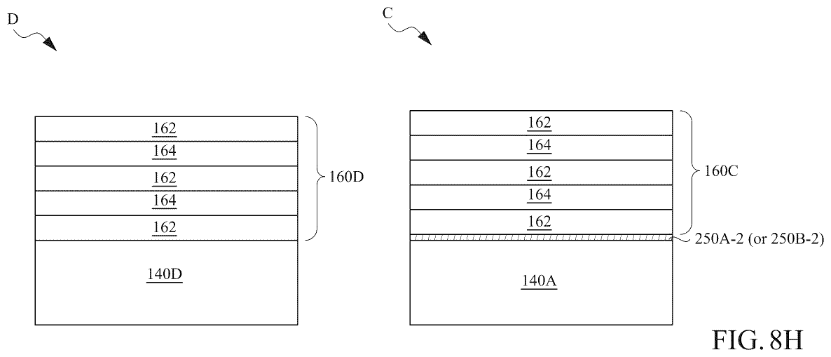

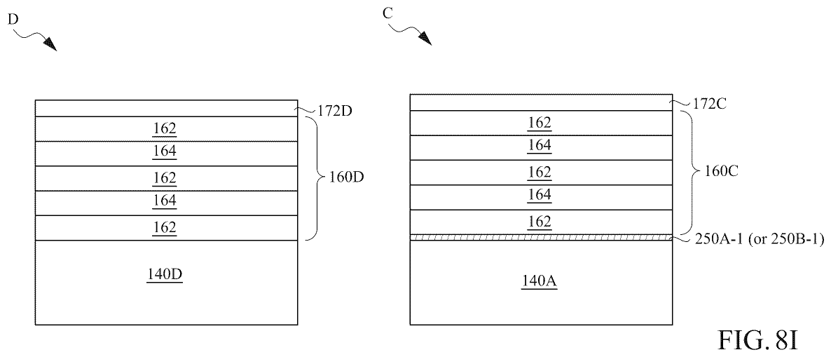

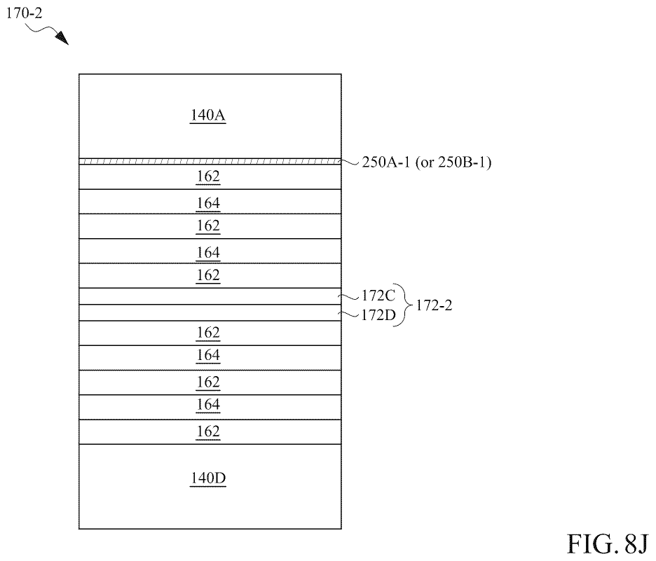

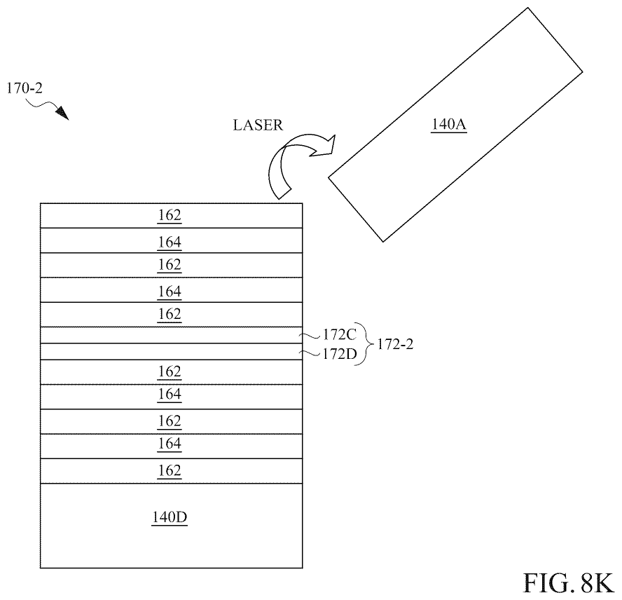

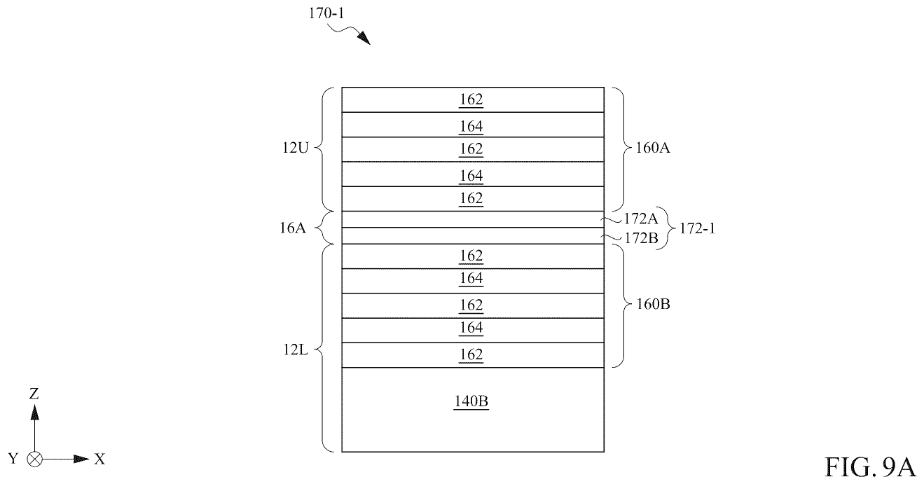

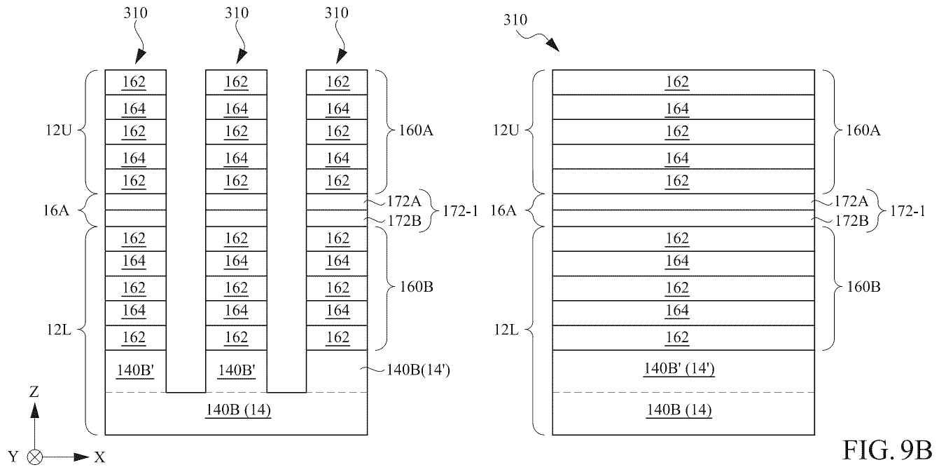

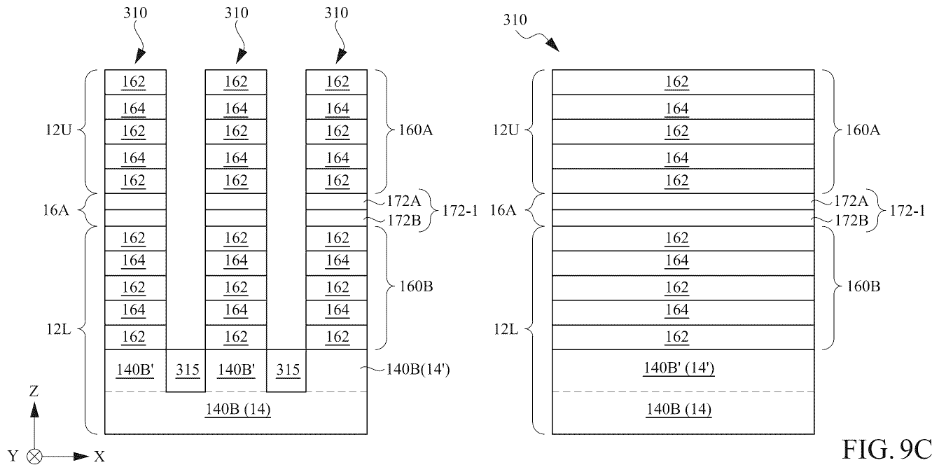

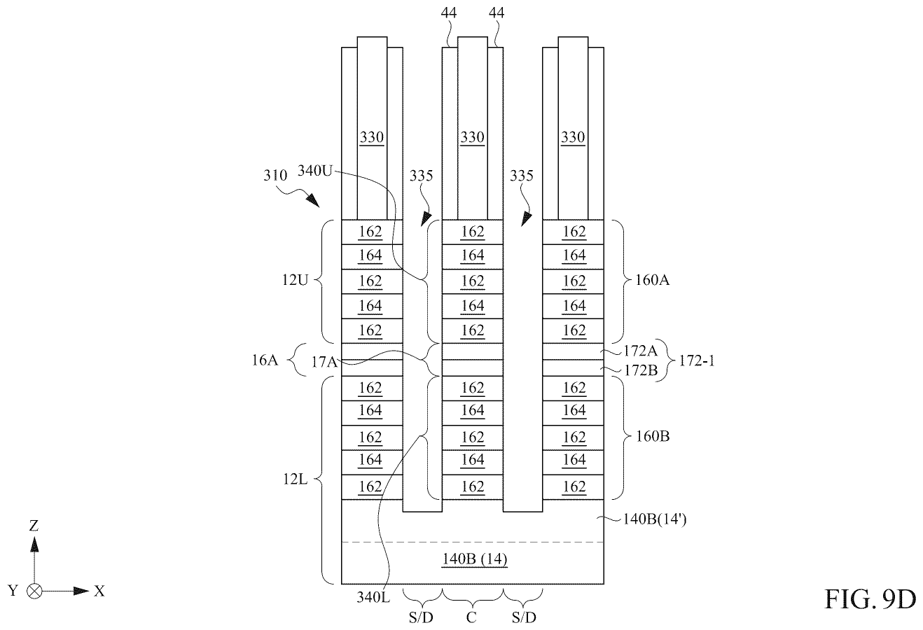

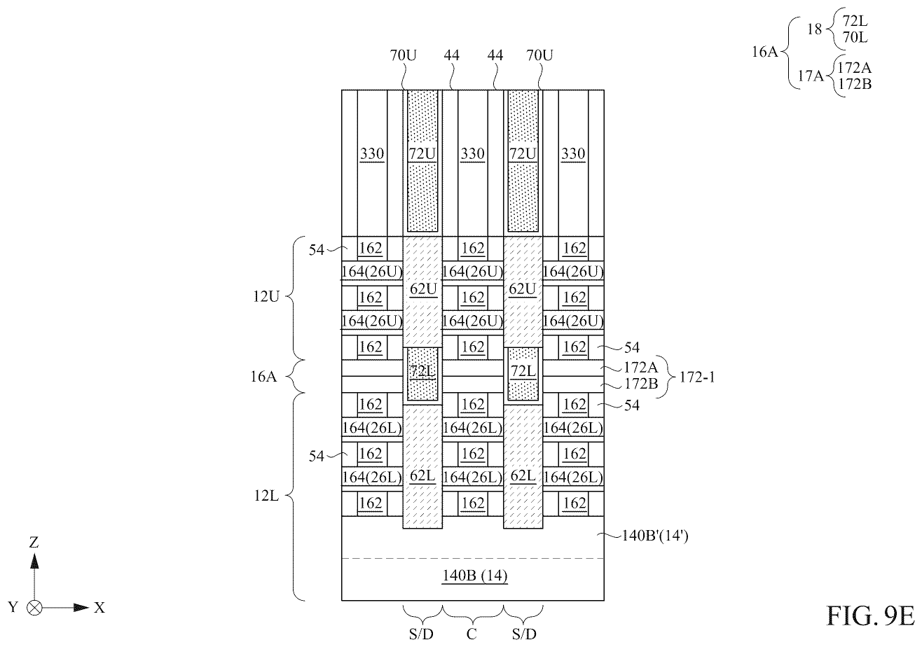

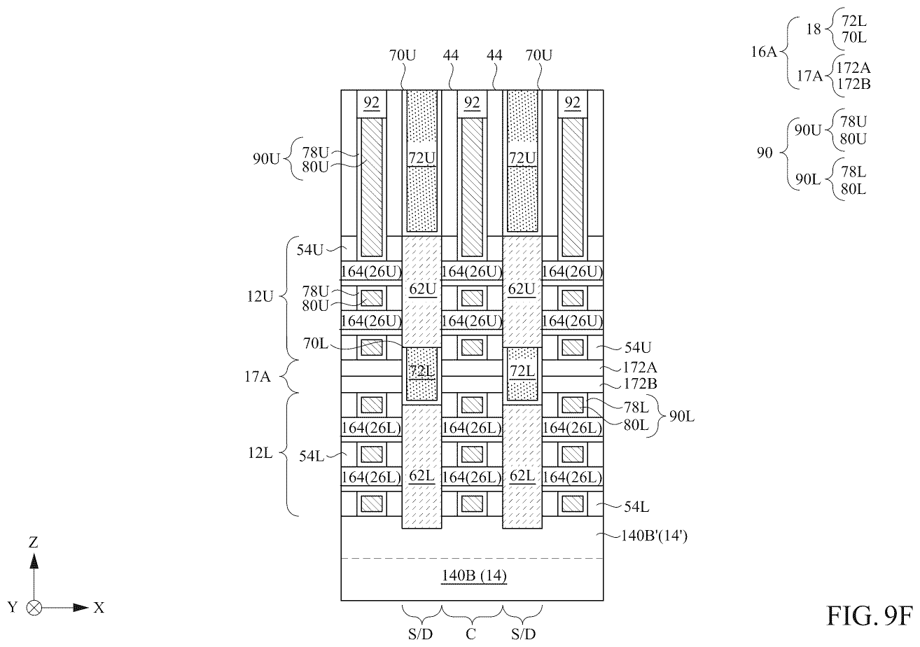

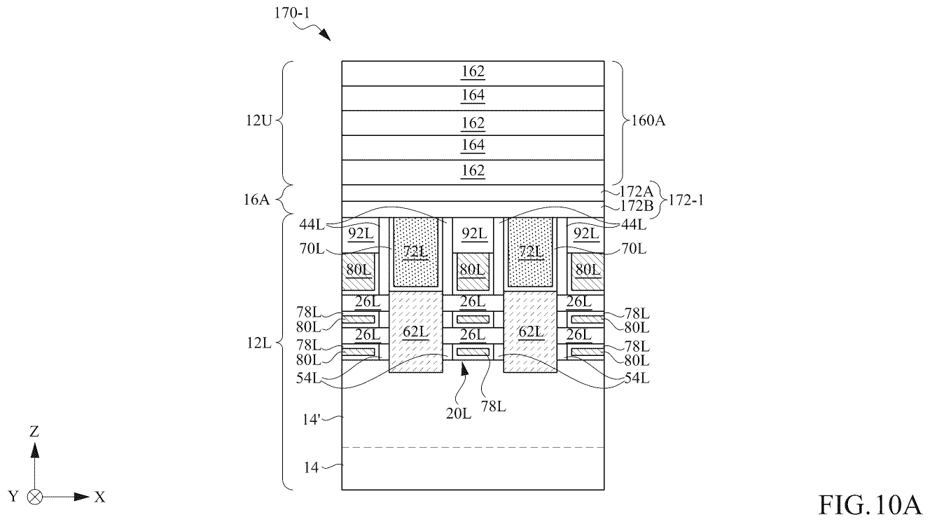

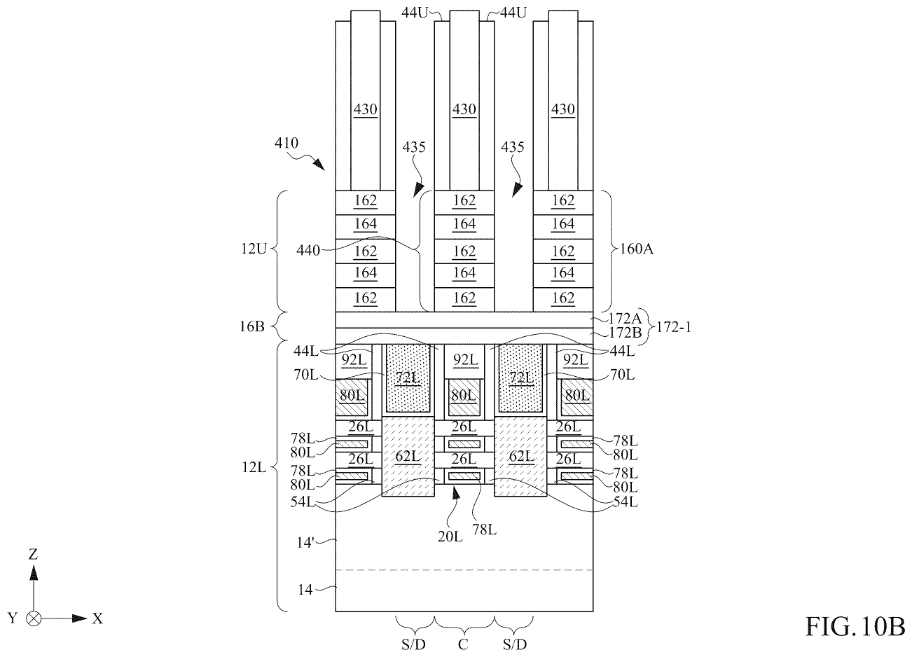

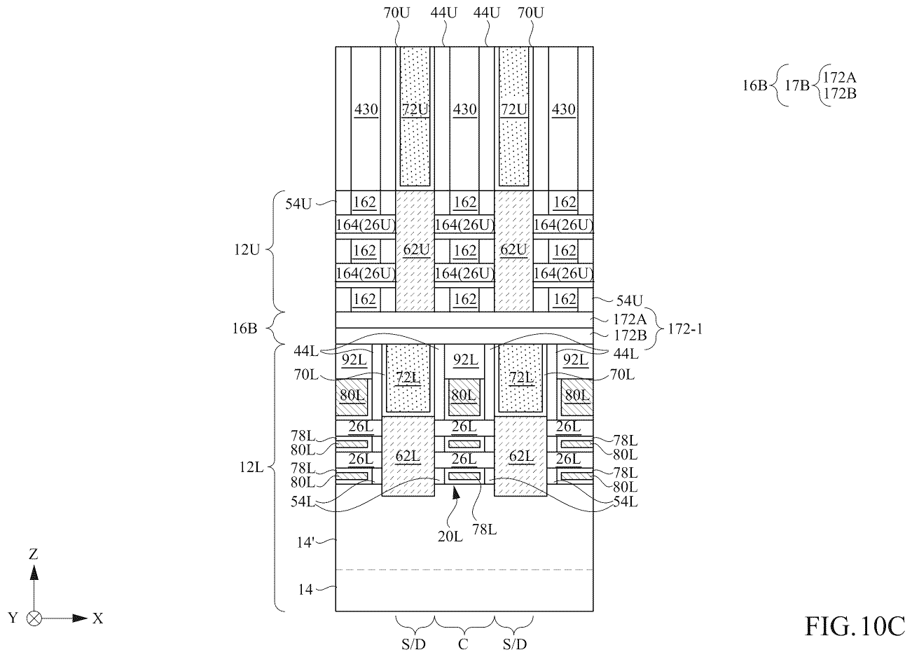

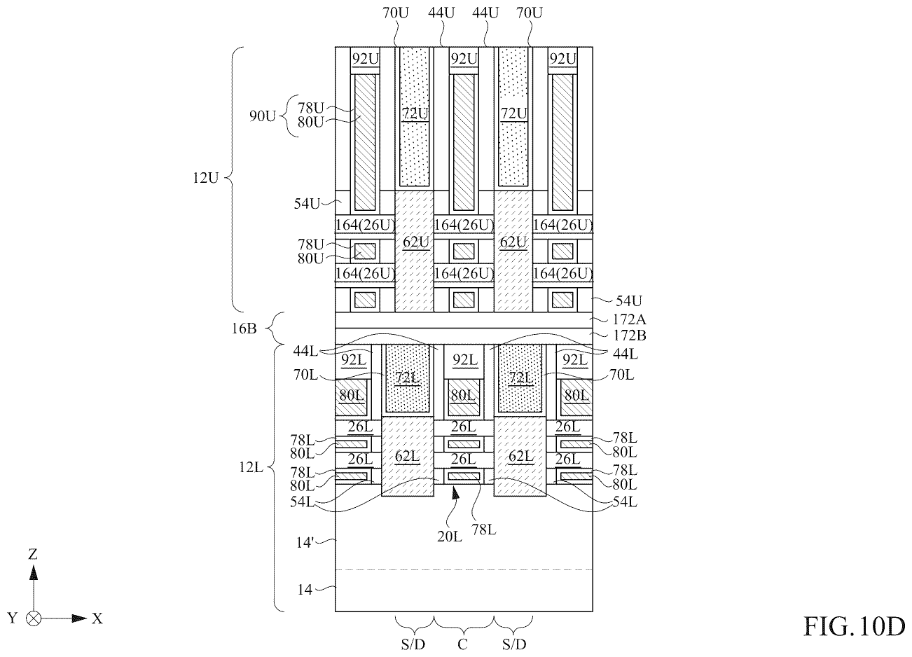

FIG. 2 is a flow chart of a method 100, in portion or entirety, for preparing a stacked structure according to various aspects of the present disclosure. Method 100 implements a debonding technique, such as those described herein, that enables reuse of a carrier substrate, thereby reducing costs associated with fabricating semiconductor devices. In some embodiments, method 100 may be implemented to prepare stacked device precursors, which may be processed to form stacked device structures, such as stacked device structure 10A of FIG. 1A and/or stacked device structure 10B of FIG. 1B. FIG. 2 has been simplified for the sake of clarity to better understand the inventive concepts of the present disclosure. Additional steps may be provided before, during, and after method 100, and some of the steps described may be moved, replaced, or eliminated for additional embodiments of method 100.

At block 105, method 100 includes receiving and/or forming a first device component and a second device component. The first device component includes a release layer and a carrier substrate. The release layer is configured to facilitate damage-free debonding of the carrier substrate from a stacked structure that includes the first device component and the second device component. For example, the release layer is formed of a two-dimensional material or a semiconductor oxide material. In some embodiments, the first device component is a first device precursor, and the second device component is a second device precursor. The first device precursor may include a first semiconductor layer stack disposed over a first substrate, the first substrate may be the carrier substrate, and the release layer may be disposed between the first substrate and the first semiconductor layer stack. The second device precursor may include a second semiconductor layer stack disposed over a second substrate. In some embodiments, the first device component is a first device precursor, and the second device component is a second device (e.g., a prefabricated device). At block 110, method 100 includes bonding the first device component and the second device component to form a stacked structure. The stacked structure includes the first device component disposed over the second device component. In embodiments where the first device component and the second device component are the first device precursor and the second device precursor, respectively, the stacked structure may be referred to as a semiconductor layer stack precursor or a device stack precursor. In embodiments where the first device component is a first device precursor and the second device component is a second device, the stacked structure may be referred to as a device stack precursor.

Method 100 further includes removing the release layer and the carrier substrate from the first device component at block 115 (i.e., a debonding step) and reusing the carrier substrate at block 120. In some embodiments, the release layer and the carrier substrate are removed by peeling (e.g., where the release layer is formed of two-dimensional material) or laser (e.g., where the release layer is formed of semiconductor oxide material) to enable reuse of the carrier substrate. In some embodiments, the carrier substrate may be reused to form a third device precursor that is subsequently bonded to a fourth device precursor, such as described herein. In some embodiments, the release layer is removed from the carrier substrate during debonding (i.e., at block 115). In some embodiments, the release layer is not removed from the carrier substrate during debonding. In such embodiments, the release layer may remain on the carrier substrate and be reused, for example, to form the third device precursor, or the release layer may be removed from the carrier substrate at block 125 (and thus not reused). In some embodiments, method 100 further includes processing the stacked structure to form a device stack at block 130, such as a first device disposed over a second device. For example, the semiconductor layer stack precursor may be processed to form the first device and the second device from the first device precursor and the second device precursor, respectively. In another example, the device stack precursor may be processed to form the first device from the first device precursor over the second device. The first device and the second device may be gate-all-around (GAA) transistors, fin-like field effect transistors (FinFETs), planar transistors, other type of transistors, or combinations thereof. The first device and the second device may provide a CFET.

FIGS. 3A-3K illustrate a process flow, in portion or entirety, for preparing stacked structures, according to various aspects of the present disclosure. FIG. 4 illustrates a process flow, in portion or entirety, for reusing carrier substrates of stacked structures, such as the stacked structures prepared by the process flow of FIGS. 3A-3K, according to various aspects of the present disclosure. The process flow illustrated in FIGS. 3A-3K implements a debonding technique that enables reuse of a carrier substrate, such as illustrated in FIG. 4, thereby reducing costs associated with fabricating devices. In some embodiments, the process flow may be implemented to prepare stacked precursors, which may be processed to form stacked device structures, such as stacked device structure 10A of FIG. 1A and/or stacked device structure 10B of FIG. 1B. FIGS. 3A-3K and FIG. 4 have been simplified for the sake of clarity to better understand the inventive concepts of the present disclosure. Additional steps may be provided before, during, and after the various process steps depicted in FIGS. 3A-3K and FIG. 4, and some of the steps described may be moved, replaced, or eliminated for additional embodiments of the process flow depicted in FIGS. 3A-3K and FIG. 4. Further, additional features may be added in FIGS. 3A-3K and FIG. 4, and some of the features described below may be replaced, modified, or eliminated in other embodiments of FIGS. 3A-3K and FIG. 4.

Referring to FIG. 3A, a substrate 140A is provided for a device component A. As described herein, substrate 140A is a carrier substrate. For example, substrate 140A temporarily forms a portion of device component A, and substrate 140A may be used to support and/or transport other layers and/or features of device component A during processing. In some embodiments, substrate 140A is a semiconductor substrate. The semiconductor substrate may include an elementary semiconductor, such as silicon and/or germanium; a compound semiconductor, such as silicon carbide, gallium arsenide, gallium phosphide, indium phosphide, indium arsenide, indium antimonide, or combinations thereof; an alloy semiconductor, such as SiGe, GaAsP, AlInAs, AlGaAs, GaInAs, GaInP, GaInAsP, or combinations thereof; or combinations thereof. In the depicted embodiment, substate 140A is a semiconductor carrier. For example, substrate 140A may be a silicon substrate. In some embodiments, substrate 140A is a glass carrier, a ceramic carrier, a polymer carrier, or other suitable carrier.

Referring to FIG. 3B, a release layer 150A-1 having a thickness t1 is formed over substrate 140A. In the depicted embodiment, release layer 150A-1 is formed of a two-dimensional (2D) material that facilitates adhesion and/or attachment of a material layer(s) to substrate 140A and/or release layer 150A-1, yet sufficiently weakens such adhesion and/or attachment (e.g., by reducing mechanical forces between the material layer(s) and substrate 140A) to enable removal of substrate 140A by peeling. In other words, an adhesion/bond strength between release layer 150A-1 and the material layer(s) (e.g., a multilayer stack 160A) is less than an adhesion/bond strength between substrate 140A and the material layer(s). In some embodiments, the 2D material is graphene, and release layer 150A-1 is a graphene layer. In some embodiments, the 2D material is hexagonal boron nitride (2D-hBN), and release layer 150A-1 is a 2D-hBN layer. Release layer 150A-1 (also referred to as a 2D material layer) is formed by a suitable deposition process, such as chemical vapor deposition (CVD). In some embodiments, release layer 150A-1 is directly deposited/grown on substrate 140A.

Referring to FIG. 3C, multilayer stack 160A is formed on substrate 140A, such that release layer 150A-1 is between multilayer stack 160A and substrate 140A. In the depicted embodiment, multilayer stack 160A includes semiconductor layers 162 and semiconductor layers 164. Semiconductor layers 162 and semiconductor layers 164 are stacked vertically (e.g., along a z-direction) in an interleaving and/or alternating configuration from a surface of substrate 140A having release layer 150A-1 formed thereon (e.g., a top of substrate 140A). A composition of semiconductor layers 162 is different than a composition of semiconductor layers 164, for example, to achieve etch selectivity therebetween. For example, semiconductor layers 162 and semiconductor layers 164 include different materials, constituent atomic percentages, constituent weight percentages, other characteristics, or combinations thereof. In some embodiments, semiconductor layers 162 include silicon germanium, and semiconductor layers 164 include silicon. In some embodiments, semiconductor layers 162 and semiconductor layers 164 include the same material but with different constituent atomic percentages. For example, semiconductor layers 162 and semiconductor layers 164 may both include silicon germanium, but with different germanium atomic percentages. Semiconductor layers 162 and semiconductor layers 164 may include any combination of materials that provides desired etching selectivity, desired oxidation rate differences, desired performance characteristics (e.g., materials that maximize current flow), other desired characteristics, or combinations thereof.

Semiconductor layers 164 or portions thereof may form channels of transistors. In the depicted embodiment, multilayer stack 160A includes three semiconductor layers 162 and two semiconductor layers 164. After processing of multilayer stack 160A (such as that associated with processing of a stacked structure as described herein), this configuration may result in transistors having two channels. In some embodiments, multilayer stack 160A includes different numbers of semiconductor layers 162 and/or semiconductor layers 164 depending, for example, on a number of channels desired for the transistors. For example, multilayer stack 160A may include two to six semiconductor layer pairs, each of which has a respective semiconductor layer 162 and a respective semiconductor layer 164. In some embodiments, semiconductor layers 162 are removed and/or replaced during processing of multilayer stack 160A, and semiconductor layers 162 may thus be referred to as sacrificial layers.

Multilayer stack 160A may be formed by depositing semiconductor layers 162 and semiconductor layers 164 over substrate 140A in the depicted interleaving and/or alternating configuration. In some embodiments, the depositing includes epitaxially growing semiconductor layers 162 and semiconductor layers 164. For example, a first one of semiconductor layers 162 is epitaxially grown on release layer 150A-1 and/or substrate 140A, a first one of semiconductor layers 164 is epitaxially grown on the first one of semiconductor layers 162, a second one of semiconductor layers 162 is epitaxially grown on the first one of semiconductor layers 164, and so on until multilayer stack 160A has a desired number of semiconductor layers 162 and a desired number of semiconductor layers 164. In such embodiments, semiconductor layers 162 and semiconductor layers 164 may be referred to as epitaxial layers, and multilayer stack 160A may be referred to as an epitaxial stack. Epitaxial growth of semiconductor layers 162 and semiconductor layers 164 is provided by molecular beam epitaxy (MBE), CVD, metalorganic CVD (MOCVD), other suitable epitaxial growth process, or combinations thereof.

Thickness t1 is configured to minimize an impact of release layer 150A-1 on formation of multilayer stack 160A on substrate 140A (e.g., by minimizing lattice mismatch) and/or sufficiently weaken mechanical forces between multilayer stack 160A and substrate 140A, such that substrate 140A may be removed from multilayer stack 160A (e.g., by peeling) with minimal to no damage thereto. For example, if release layer 150A-1 is too thin (e.g., t1 is less than one monolayer), adhesion and/or attachment of substrate 140A and multilayer stack 160A is negligibly reduced, and multilayer stack 160A may be damaged during removal of substrate 140A therefrom (e.g., during peeling) even with release layer 150A-1 therebetween. If release layer 150A-1 is too thick (e.g., t1 is greater than three monolayers), a lattice mismatch between release layer 150-1 and multilayer stack 160A (e.g., semiconductor layer 162 thereof) may cause defects and/or undesired amounts and/or types of stress in multilayer stack 160A during formation thereof. In some embodiments, thickness t1 is one monolayer to three monolayers. In some embodiments, thickness t1 and/or a composition of release layer 150-1 is configured to provide a lattice mismatch between release layer 150-1 and multilayer stack 160A (e.g., semiconductor layer 162 thereof) that is comparable to a lattice mismatch between substrate 140A and multilayer stack 160A (e.g., semiconductor layer 162 thereof).

Referring to FIG. 3D, a device component B is received and/or formed for stacking with device component A. Device component B includes a substrate 140B and a multilayer stack 160B (including respective semiconductor layers 162 and respective semiconductor layers 164). Substrate 140B may be configured the same as and/or different than substrate 140A, and substate 140B may be configured as and/or include any of the materials described above with reference to substrate 140A. Multilayer stack 160B may be configured the same as and/or different than multilayer stack 160A, and multilayer stack 160B may be configured as and/or include any of the materials described above with reference to multilayer stack 160A. In some embodiments, substrate 140B is a silicon substrate, semiconductor layers 162 are silicon germanium layers, and silicon layers 164 are silicon layers. In some embodiments, such as where device component A and device component B are processed to form opposite type transistors, multilayer stack 160A and multilayer stack 160B may have semiconductor layers of different compositions and/or include different arrangements of semiconductor layers.

Referring to FIG. 3E and FIG. 3F, a stacked structure 170-1 is formed by bonding and/or attaching device component A and device component B. Referring to FIG. 3E, a bonding layer 172A may be formed over multilayer stack 160A (e.g., on semiconductor layer 162 thereof) of device component A, and a bonding layer 172B may be formed over multilayer stack 160B (e.g., on semiconductor layer 162 thereof) of device component B. Bonding layer 172A and bonding layer 172B include any suitable material(s) that facilitate bonding thereof, and thus bonding of device component A with device component B (and, more specifically, bonding of multilayer stack 160A and multilayer stack 160B). In some embodiments, bonding layer 172A and bonding layer 172B include materials that facilitate dielectric-to-dielectric bonding and electrically isolate device component A and device component B. In some embodiments, bonding layer 172A and bonding layer 172B include silicon and oxygen, nitrogen, carbon, or combinations thereof (e.g., silicon oxide, silicon nitride (SIN), silicon oxynitride (SiON), silicon carbonitride (SiCN), silicon oxycarbide (SiOC), silicon oxycarbonitride (SiOCN), etc.). For example, bonding layer 172A and bonding layer 172B may be SiO₂ layers, SiN layers, SiCN layers, SiC layers, or SiOC layers. In some embodiments, bonding layer 172A and bonding layer 172B include boron and oxygen, nitrogen, carbon, or combinations thereof (e.g., boron nitride (BN), boron carbonitride (BCN), etc.). For example, bonding layer 172A and bonding layer 172B may be BN layers or BCN layers. In some embodiments, bonding layer 172A and bonding layer 172B include metal and oxygen, nitrogen, carbon, or combinations thereof (e.g., aluminum oxide, aluminum nitride, hafnium oxide, yttrium oxide, etc.). For example, bonding layer 172A and bonding layer 172B may be Al₂O₃ layers, AlN layers, HfO₂ layers, or Y₂O₃ layers. In some embodiments, bonding layer 172A and bonding layer 172B include different dielectric materials. For example, bonding layer 172A may be an oxygen-containing dielectric layer, such as an oxide layer, and bonding layer 172B may be a silicon-and-nitrogen-containing dielectric layer, such as a SiN layer, an SiON layer, or a SiCN layer. In another example, bonding layer 172A may be an oxygen-containing dielectric layer, and bonding layer 172B may be a boron-and-nitrogen-containing dielectric layer, such as a BN layer or a BCN layer.

Referring to FIG. 3F, the bonding may include flipping over device component A, aligning device component A with device component B, and attaching device component A to device component B, thereby providing stacked structure 170-1. For example, the bonding includes bringing bonding layer 172A of device component A into contact with bonding layer 172B of device component B (or vice versa). Bonding layer 172A and bonding layer 172B may be brought into contact under a temperature, a pressure, an atmosphere, or combinations thereof for a time that effectuates bonding of bonding layer 172A and bonding layer 172B. For example, a given bonding pressure and/or a given bonding temperature may be applied to device component A, bonding layer 172A thereof, device component B, bonding layer 172B thereof, or combinations thereof for a given bonding time to effectuate chemical bonding/adhesion of bonding surfaces of bonding layer 172A and bonding layer 172B. In some embodiments, a plasma activation process (e.g., an oxygen plasma treatment) may be performed on bonding layer 172A and bonding layer 172B before bringing bonding layer 172A of device component A into contact with bonding layer 172B of device component B (or vice versa). In such embodiments, parameters of the bonding process may be configured to effectuate chemical bonding/adhesion of the plasma-activated surfaces of bonding layer 172A and bonding layer 172B.

Referring to FIG. 3G, substrate 140A and release layer 150A-1 are removed from stacked structure 170-1 by peeling. In the depicted embodiment, because release layer 150-1 (e.g., a graphene layer and/or a hexagonal boron nitride layer) weakens mechanical forces between substrate 140A and multilayer stack 160A, and thus reduces adhesion and/or attachment of substrate 140A and multilayer stack 160A, substrate 140A is removed without (or negligibly) damaging multilayer stack 160A. In some embodiments, mechanical means and/or physical means are used to peel substrate 140A from multilayer stack 160A. In some embodiments, stacked structure 170-1 and/or an environment around stacked structure 170-1 (e.g., an ambient and/or a wafer stage) may be heated before and/or during the peeling. In some embodiments, the peeling may include bending stacked structure 170-1, or portions thereof.

After bonding and removal of substrate 140A (and release layer 150-1) by peeling, stacked structure 170-1 includes device component A (including multilayer stack 160A, but no longer including substrate 140A and release layer 150A-1), device component B, and a bonding structure 172-1 between device component A and device component B. Bonding structure 172-1 includes bonding layer 172A, bonding layer 172B, and any layer formed therebetween by intermixing of and/or bonding of bonding layer 172A and bonding layer 172B. In some embodiments, where stacked structure 170-1 is provided for monolithically fabricating a transistor stack, such as that of stacked device structure 10A, device component B may provide a device precursor for fabricating a lower transistor (e.g., transistor 20L), device component A may provide a device precursor for fabricating an upper transistor (e.g., transistor 20U), and the device precursors may be processed to form the lower transistor and the upper transistor, respectively. In such embodiments, bonding structure 172-1 may provide an isolation structure, or portion thereof, between the lower transistor and the upper transistor. For example, bonding structure 172-1 may provide isolation structures 17A (of isolation structure 16A) between channel regions of transistor 20L and transistor 20U of stacked device structure 10A.

Referring to FIGS. 3H-3K, substrate 140A may be reused to prepare and/or provide other stacked structures, such as a stacked structure 170-2. In the depicted embodiment, release layer 150A-1 remains on substrate 140A after peeling, and release layer 150A-1 is also reused when preparing and/or providing stacked structure 170-2. For example, referring to FIG. 3H, substrate 140A and release layer 150-1 may form a portion of another device component, such as a device component C, and a multilayer stack 160C of device component C is formed over release layer 150-1 and/or substrate 140A. Multilayer stack 160C (including respective semiconductor layers 162 and respective semiconductor layers 164) may be configured the same as and/or different than multilayer stack 160A, and multilayer stack 160C may be configured as and/or include any of the materials described above with reference to multilayer stack 160A. Further, referring to FIG. 3H, a device component D is received and/or formed for stacking with device component C. Device component D includes a substrate 140D and a multilayer stack 160D, which includes respective semiconductor layers 162 and respective semiconductor layers 164. Substrate 140D may be configured the same as and/or different than substrate 140A, and substate 140D may be configured as and/or include any of the materials described above with reference to substrate 140A. Multilayer stack 160D may be configured the same as and/or different than multilayer stack 160A, and multilayer stack 160D may be configured as and/or include any of the materials described above with reference to multilayer stack 160A.

Stacked structure 170-2 is formed by bonding and/or attaching device component C and device component D. For example, referring to FIG. 3I, a bonding layer 172C and a bonding layer 172D may be formed over multilayer stack 160C and multilayer stack 160D, respectively. Bonding layer 172C and bonding layer 172D include any suitable material(s) that facilitate bonding thereof, and thus bonding of device component C with device component D (and, more specifically, bonding of multilayer stack 160C and multilayer stack 160D). Bonding layer 172C may be configured the same as and/or different than bonding layer 172A, and bonding layer 172C may be configured as and/or include any of the materials described above with reference to bonding layer 172A. Bonding layer 172D may be configured the same as and/or different than bonding layer 172B, and bonding layer 172D may be configured as and/or include any of the materials described above with reference to bonding layer 172B.

Referring to FIG. 3J, the bonding may include flipping over device component C, aligning device component C with device component D, and attaching device component C to device component D, thereby providing stacked structure 170-2. For example, the bonding includes bringing bonding layer 172C of device component C into contact with bonding layer 172D of device component D (or vice versa). Bonding layer 172C and bonding layer 172D may be brought into contact under a temperature, a pressure, an atmosphere, or combinations thereof for a time that effectuates bonding of bonding layer 172C and bonding layer 172D. For example, a given bonding pressure and/or a given bonding temperature may be applied to device component C, bonding layer 172C thereof, device component D, bonding layer 172D thereof, or combinations thereof for a given bonding time to effectuate chemical bonding/adhesion of bonding surfaces of bonding layer 172C and bonding layer 172D. In some embodiments, a plasma activation process (e.g., an oxygen plasma treatment) may be performed on bonding layer 172C and bonding layer 172D before bringing bonding layer 172C of device component C into contact with bonding layer 172D of device component D (or vice versa). In such embodiments, parameters of the bonding process may be configured to effectuate chemical bonding/adhesion of the plasma-activated surfaces of bonding layer 172C and bonding layer 172D.

Referring to FIG. 3K, substrate 140A and release layer 150A-1 are removed from stacked structure 170-2 by peeling. In the depicted embodiment, because release layer 150-1 (e.g., a graphene layer and/or a hexagonal boron nitride layer) weakens mechanical forces between substrate 140A and multilayer stack 160C, and thus reduces adhesion and/or attachment of substrate 140A and multilayer stack 160C, substrate 140A is removed without (or negligibly) damaging multilayer stack 160C. In some embodiments, mechanical means and/or physical means are used to peel substrate 140A from multilayer stack 160C. In some embodiments, stacked structure 170-2 and/or an environment around stacked structure 170-2 (e.g., an ambient and/or a wafer stage) may be heated before and/or during the peeling. In some embodiments, the peeling may include bending stacked structure 170-2, or portions thereof.

After bonding and removal of substrate 140A (and release layer 150-1) by peeling, stacked structure 170-2 includes device component C, device component D, and a bonding structure 172-2 between device component C and device component D. Bonding structure 172-2 includes bonding layer 172C, bonding layer 172D, and any layer formed therebetween by intermixing of and/or bonding of bonding layer 172C and bonding layer 172D. In some embodiments, where stacked structure 170-2 is provided for monolithically fabricating a transistor stack, such as that of stacked device structure 10A, device component D may provide a device precursor for fabricating a lower transistor (e.g., transistor 20L), device component C may provide a device precursor for fabricating an upper transistor (e.g., transistor 20U), and the device precursors may be processed to form the lower transistor and the upper transistor, respectively. In such embodiments, bonding structure 172-2 may provide an isolation structure, or portion thereof, between the lower transistor and the upper transistor. For example, bonding structure 172-2 may provide isolation structures 17A (of isolation structure 16A) between channel regions of transistor 20L and transistor 20U of stacked device structure 10A.

After removal of substrate 140A from stacked structure 170-2, substrate 140A (and, in some embodiments, release layer 150-1) may be reused again multiple times. The process flow of FIGS. 3A-3K thus enables multiple uses of a single carrier substrate, which significantly reduces fabrication costs, such as those associated with preparing semiconductor layer stack precursors, which may be processed to form stacked device structures.

Referring to FIG. 4, in some embodiments, release layer 150A-1 is removed from substrate 140A before reuse of substrate 140A (i.e., release layer 150A-1 is not reused). For example, a planarization process, such as a chemical mechanical polishing (or planarization) (CMP), is performed to remove release layer 150A-1 from substrate 140A. Substrate 140A may then be reused in various manners. In some embodiments, substrate 140A is reused to provide a carrier substrate for a subsequently formed device component, such as device component C. In such embodiments, another release layer, such as a release layer 150A-2, is formed on substrate 140A before forming multilayer stack 160C thereon (e.g., FIG. 3H) and attaching device component C to device component D to form stacked structure 170-2 (e.g., FIG. 3I and FIG. 3J). In such embodiments, release layer 150A-2 is disposed between multilayer stack 160C and substrate 140A, and release layer 150A-2 and substrate 140A are removed from device component C by peeling (e.g., FIG. 3K). Release layer 150A-2 is configured and formed similar to release layer 150A-1. In other embodiments, substrate 140A is reused to provide a substrate for a device component, such as device component D, and substrate 140A may not be removed from a stacked structure of which it forms a portion of. For example, substrate 140A may replace substrate 140D, multilayer stack 160C may be formed over a different carrier substrate (which is subsequently removed by peeling), and substrate 140A may remain a part of stacked structure 170-2. Further, in such example, after processing stacked device structure 170-2 (e.g., a stack of device precursors) to form a transistor stack (e.g., transistor 20U and transistor 20L, respectively, from device component C and device component D), substrate 140A (a reused carrier substrate) may provide a base substrate of the transistor stack, such as substrate 14 of stacked device structure 10A, over which transistor 20L and transistor 20L are formed.

FIGS. 5A-5J illustrate another process flow, in portion or entirety, for preparing stacked structures, according to various aspects of the present disclosure. The process flow illustrated in FIGS. 5A-5J implements a debonding technique that enables reuse of a carrier substrate, such as illustrated in FIG. 4, thereby reducing costs associated with fabricating devices. In some embodiments, the process flow may be implemented to prepare stacked precursors, which may be processed to form stacked device structures, such as stacked device structure 10A and/or stacked device structure 10B. Since the process flow illustrated in FIGS. 5A-5J is similar in many respects to the process flow illustrated in FIGS. 3A-3K, similar features are identified by the same reference numerals for clarity and simplicity. FIGS. 5A-5J have been simplified for the sake of clarity to better understand the inventive concepts of the present disclosure. Additional steps may be provided before, during, and after the various process steps depicted in FIGS. 5A-5J, and some of the steps described may be moved, replaced, or eliminated for additional embodiments of the process flow depicted in FIGS. 5A-5J. Further, additional features may be added in FIGS. 5A-5J, and some of the features described may be replaced, modified, or eliminated in other embodiments of FIGS. 5A-5J.

Referring to FIG. 5A, device component A and device component B are received and/or formed for stacking, such as described above with reference to FIGS. 3A-3D. For example, substrate 140A is provided for device component A (such as described above with reference to FIG. 3A), release layer 150A-1 having thickness t1 is formed over substrate 140A (such as described above with reference to FIG. 3B), multilayer stack 160A is formed on substrate 140A (such as described above with reference to FIG. 3C), and device component B is received and/or formed for stacking with device component A (such as described above with reference to FIG. 3D). In contrast to the process flow of FIGS. 3A-3K, in FIG. 5A, to further protect multilayer stack 160A from damage during peeling, a cap layer 175-1 is formed over release layer 150A-1 before forming multilayer stack 160A, such that cap layer 175-1 is also disposed between multilayer stack 160A and substrate 140A. In some embodiments, cap layer 175-1 is a semiconductor layer having a composition different than a composition of an adjacent layer of multilayer stack 160A (e.g., one of semiconductor layers 162). In the depicted embodiment, cap layer 175-1 is a silicon layer. Cap layer 175-1 has any suitable thickness. In the depicted embodiment, a thickness of cap layer 175-1 is less than a thickness of semiconductor layers 162 and greater than a thickness of release layer 150-1. In some embodiments, cap layer 175-1 is considered a portion of multilayer stack 160A.

Referring to FIG. 5B and FIG. 5C, stacked structure 170-1 is formed by bonding and/or attaching device component A and device component B. For example, bonding layer 172A and bonding layer 172B may be formed over multilayer stack 160A and multilayer stack 160B, respectively (FIG. 5B) (such as described above with reference to FIG. 3E), and bonding layer 172A may be bonded and/or attached to bonding layer 172B (FIG. 5C) (such as described above with reference to FIG. 3F), thereby providing stacked structure 170-1 with bonding structure 172-1. In FIG. 5C, stacked structure 170-1 further includes cap layer 175-1 between multilayer stack 160A and release layer 150A-1 of device component A.

Referring to FIG. 5D, substrate 140A and release layer 150A-1 are removed from stacked structure 170-1 by peeling (such as described above with reference to FIG. 3G). In the depicted embodiment, substrate 140A and release layer 150A-1 are removed from cap layer 175-1, instead of multilayer stack 160A. Inserting cap layer 175-1 between release layer 150-1 and multilayer stack 160A provides additional protection to multilayer stack 160A during removal of substrate 140A. Further, because release layer 150-1 weakens mechanical forces between substrate 140A and cap layer 175-1 (and/or multilayer stack 160A), and thus reduces adhesion and/or attachment of substrate 140A and cap layer 175-1 (and/or multilayer stack 160A), substrate 140A is removed without (or negligibly) damaging multilayer stack 160A. In some embodiments, mechanical means and/or physical means are used to peel substrate 140A from cap layer 175-1. In some embodiments, stacked structure 170-1 and/or an environment around stacked structure 170-1 may be heated before and/or during the peeling. In some embodiments, the peeling may include bending stacked structure 170-1, or portions thereof.

Referring to FIG. 5E, cap layer 175-1 is removed from stacked structure 170-1 (e.g., multilayer stack 160A thereof) by any suitable process. For example, a planarization process, such as CMP, is performed to remove cap layer 175-1. After bonding and removal of substrate 140A (and release layer 150-1) by peeling and cap layer 175-1 (e.g., by CMP), stacked structure 170-1 includes device component A (including multilayer stack 160A, but no longer including substrate 140A, release layer 150A-1, and cap layer 175-1), device component B, and bonding structure 172-1 therebetween (such as described above with reference to FIG. 3G).

Referring to FIGS. 5F-5J, substrate 140A (and, in some embodiments, release layer 150-1) may be reused to prepare and/or provide other stacked structures, such as stacked structure 170-2. For example, referring to FIG. 5F, substrate 140A and release layer 150-1 may form a portion of another device component, such as device component C, a cap layer 175-2 (which may be similar to cap layer 175-1) may be formed over release layer 150-1 before forming multilayer stack 160C over release layer 150-1 and/or substrate 140A (such as described with reference to FIG. 5A), and device component D is received and/or formed for stacking with device component C (such as described above with reference to FIG. 3H). In some embodiments, release layer 150-1 is removed before forming cap layer 175-2, and another release layer, such as release layer 150-2, is formed over substrate 140A, such as described with reference to FIG. 4. In such embodiments, cap layer 175-2 may be formed over release layer 150-2. Referring to FIG. 5G and FIG. 5H, device component C may be bonded and/or attached to device component D, such as described above with reference to FIG. 3I and FIG. 3J, to provide stacked structure 170-2. In FIG. 5H, stacked structure 170-2 further includes cap layer 175-2 between multilayer stack 160C and release layer 150A-1 of device component C.

Referring to FIG. 5I, substrate 140A and release layer 150A-1 are removed from stacked structure 170-2 by peeling, such as described above with reference to FIG. 5D. In the depicted embodiment, substrate 140A and release layer 150A-1 are removed from cap layer 175-2, instead of multilayer stack 160C. Inserting cap layer 175-2 between release layer 150-1 and multilayer stack 160C provides additional protection to multilayer stack 160C during removal of substrate 140A. Referring to FIG. 5J, cap layer 175-2 may be removed from stacked structure 170-2 (e.g., multilayer stack 160C thereof), such as described above with reference to FIG. 5E. For example, cap layer 175-2 is removed by CMP. After removal of substrate 140A from stacked structure 170-2, substrate 140A (and, in some embodiments, release layer 150-1) may be reused again multiple times. The process flow of FIGS. 5A-5J thus enables multiple uses of a single carrier substrate (and release layer), which significantly reduces fabrication costs.

FIGS. 6A-6M illustrate yet another process flow, in portion or entirety, for preparing stacked structures, according to various aspects of the present disclosure. The process flow illustrated in FIGS. 6A-6M implements a debonding technique that enables reuse of a carrier substrate, such as illustrated in FIG. 4, thereby reducing costs associated with fabricating devices. In some embodiments, the process flow may be implemented to prepare stacked precursors, which may be processed to form stacked device structures, such as stacked device structure 10A and/or stacked device structure 10B. Since the process flow depicted in FIGS. 6A-6M is similar in many respects to the process flow depicted in FIGS. 3A-3K, similar features are identified by the same reference numerals for clarity and simplicity. FIGS. 6A-6M have been simplified for the sake of clarity to better understand the inventive concepts of the present disclosure. Additional steps may be provided before, during, and after the various process steps depicted in FIGS. 6A-6M, and some of the steps described may be moved, replaced, or eliminated for additional embodiments of the process flow depicted in FIGS. 6A-6M. Further, additional features may be added in FIGS. 6A-6M, and some of the features described may be replaced, modified, or eliminated in other embodiments of FIGS. 6A-6M.

Referring to FIG. 6A, substrate 140A is provided for device component A, such as described above with reference to FIG. 3A. Referring to FIG. 6B, a release layer 250A-1 having a thickness t2 is formed on and/or in substrate 140A. In the depicted embodiment, an oxygen treatment OT1 is performed that introduces oxygen to and/or into a portion of substrate 140A over multilayer stack 160A is subsequently formed, such as a top, upper surface of substrate 140A. In some embodiments, oxygen treatment OT1 may convert a portion of substrate 140A into release layer 250A-1. For example, where first substrate 140A is a semiconductor substrate, oxygen treatment OT1 may convert a portion of substrate 140A into semiconductor oxide, thereby providing substrate 140A with a semiconductor oxide region (release layer 250A-1). Oxygen treatment OT1 may thus oxidize a portion of substrate 140A. In some embodiments, substrate 140A is a silicon substrate, and oxygen treatment OT1 converts a portion of substrate 140A into silicon oxide. In such embodiments, release layer 250A-1 is a silicon oxide region (and/or a silicon oxide layer) of and/or over substrate 140A. In some embodiments, oxygen treatment OT1 exposes substrate 140A to an oxygen-containing gas. The oxygen-containing gas includes O₂ (diatomic oxygen), O₃ (ozone), other oxygen gas and/or constituent, or combinations thereof. In some embodiments, oxygen treatment OT1 includes heating substrate 140A and/or an environment around substrate 140A (e.g., an ambient and/or a wafer stage). In some embodiments, oxygen treatment OT1 is a thermal oxidation process.

Substrate 140A and oxygen treatment OT1 are configured to provide device component A with a release layer, such as release layer 250A-1 (e.g., semiconductor oxide, such as silicon oxide), that facilitates adhesion and/or attachment of a material layer(s) to substrate 140A and/or release layer 250A-1, yet enables removal of substrate 140A by laser treatment, as described below. For example, substrate 140A is formed of a material that is transparent to, and thus transmits, infrared (IR) radiation (also referred to as IR light and/or IR energy), such as that from an IR laser beam emitted from an IR laser, while release layer 250A-1 is formed of a material that absorbs IR radiation to enable release of substrate 140A. In some embodiments, substrate 140A transmits wavelengths of IR radiation of about 1 μm to about 10 μm. In some embodiments, release layer 250A-1 transmits smaller wavelengths of IR radiation than substrate 140A, such as wavelengths of IR radiation of about 0.2 μm to about 4 μm. As another example, a coefficient of thermal expansion (CTE) of release layer 250A-1 is greater than a CTE of first substrate 140A to enable release of substrate 140A. The greater CTE of release layer 250A-1 may enhance ablation thereof, and thus, efficiency of the laser treatment. In some embodiments, the CTE of release layer 250A-1 (e.g., silicon oxide) is about 7×10⁻⁶ per Kelvin (K⁻¹). In some embodiments, the CTE of substrate 140A (e.g., silicon substrate) is about 2.6×10⁻⁶ K⁻¹.

Referring to FIG. 6C, multilayer stack 160A is formed on substrate 140A, such as described above with reference to FIG. 3C. In the process flow of FIGS. 6A-6M, to further protect multilayer stack 160A from damage during removal of substrate 140A, a sacrificial layer 275-1 may be formed over release layer 250A-1 before forming multilayer stack 160A, such that sacrificial layer 275-1 is also disposed between multilayer stack 160A and substrate 140A. For example, a thickness and/or a composition of sacrificial layer 275-1 may be configured to prevent radiation/light emitted from a laser during debonding from reaching, and potentially modifying characteristics of, multilayer stack 160A. In some embodiments, sacrificial layer 275-1 is a semiconductor layer having a composition different than a composition of an adjacent layer of multilayer stack 160A (e.g., one of semiconductor layers 162). For example, sacrificial layer 275-1 may be a silicon layer. Sacrificial layer 275-1 has any suitable thickness. In the depicted embodiment, a thickness of sacrificial layer 275-1 is greater than a thickness of semiconductor layers 162 and greater than a thickness of release layer 250A-1. In some embodiments, sacrificial layer 275-1 is considered a portion of multilayer stack 160A.

Referring to FIG. 6D, device component B is received and/or formed for stacking with device component A, such as described above with reference to FIG. 3D. Referring to FIG. 6E and FIG. 6F, stacked structure 170-1 is formed by bonding and/or attaching device component A and device component B. For example, bonding layer 172A and bonding layer 172B may be formed over multilayer stack 160A and multilayer stack 160B, respectively (FIG. 6E), such as described above with reference to FIG. 3E, and bonding layer 172A may be bonded and/or attached to bonding layer 172B (FIG. 6F), such as described above with reference to FIG. 3F, thereby providing stacked structure 170-1 with bonding structure 172-1. In the depicted embodiment, device component A of stacked structure 170-1 includes release layer 250A-1 and sacrificial layer 275-1 disposed between substate 140A and multilayer stack 160A.

Referring to FIG. 6G, substrate 140A and release layer 250A-1 are removed from stacked structure 170-1 by laser treatment. In some embodiments, laser treatment includes exposing a backside of substrate 140A to an IR laser beam 278 emitted from an IR laser 280. IR radiation from IR laser beam 278 penetrates through substrate 140A to release layer 250A-1, and release layer 250A-1 absorbs the IR radiation. As release layer 250A-1 absorbs the IR radiation and reaches its ablation threshold, substrate 140A is released from device component A. In the depicted embodiment, substrate 140A and release layer 250A-1 are removed and/or released from sacrificial layer 275-1. Inserting sacrificial layer 275-1 between release layer 250A-1 and multilayer stack 160A provides additional protection to multilayer stack 160A during removal of substrate 140A. For example, IR radiation from IR laser beam 278 may travel a distance that is greater than a thickness of substrate 140A and less than a sum of the thickness of substrate 140A, thickness t2 of release layer 250A-1, and a thickness of sacrificial layer 275-1. In such example, the IR radiation may penetrate/transmit through substrate 140A and release layer 250A-1, yet penetrate/transmit into, but not beyond, sacrificial layer 275-1. Sacrificial layer 275-1 may thus buffer impact of the IR radiation on multilayer stack 160A, and in some embodiments, prevent the IR radiation from reaching and/or penetrating multilayer stack 160A.

In some embodiments, various laser process parameters (e.g., wavelength of the IR radiation, a duration of IR laser pulses, a number of IR laser pulses, parameters of an environment of stacked structure 170-1 during the laser treatment (e.g., temperature, pressure, ambient, etc.), or combinations thereof) are configured to efficiently and quickly reach the ablation threshold of release layer 250A-1. In some embodiments, release layer 250A-1 may decompose as heated by the IR radiation, thereby enabling release of substrate 140A. In such embodiments, release layer 250A-1 may be referred to as a light-to-heat conversion layer. In some embodiments, the laser treatment breaks down and/or vaporizes release layer 250A-1 as release layer 250A-1 is exposed thereto, thereby enabling release of substrate 140A.

A wavelength of IR radiation emitted by IR laser beam 278 is configured such that the IR radiation transmits through substrate 140A, but not release layer 250A-1 (i.e., the wavelength of the IR radiation is configured such that at least a portion of the IR radiation is absorbed by release layer 250A-1). In some embodiments, IR laser beam 278 emits IR radiation with a wavelength greater than about 4 μm, such as about 4 μm to about 10 μm. Though substrate 140A may transmit IR radiation having wavelengths greater than about 4 μm, release layer 250A-1 may not absorb IR radiation having such wavelengths (in fact, release layer 250A-1 may transmit IR radiation having wavelengths of about 0.2 μm to about 4 μm), such that an ablation threshold of release layer 250A-1 cannot be reached, thereby impeding and/or preventing release of substrate 140A. Further, though release layer 250A-1 may absorb IR radiation having wavelengths greater than about 10 μm, substrate 140A may block IR radiation having such wavelengths, such that IR radiation having wavelengths greater than about 10 μm cannot reach release layer 250A-1, thereby impeding/preventing release of substrate 140A.

Thickness t2 is configured to minimize an impact of release layer 250A-1 on formation of multilayer stack 160A on substrate 140A (e.g., by minimizing lattice mismatch) and/or enable sufficient absorption of the IR radiation by release layer 250A-1, such that substrate 140A may be removed from multilayer stack 160A (e.g., by laser treatment) with minimal to no damage thereto. For example, if release layer 250A-1 is too thin (e.g., t2 is less than 1 nm), release layer 250A-1 may not absorb enough of the IR radiation during the laser treatment to facilitate release of substrate 140A. If release layer 250A-1 is too thick (e.g., t2 is greater than 20 nm), a lattice mismatch between release layer 250A-1 and multilayer stack 160A (e.g., semiconductor layer 162 thereof) and/or sacrificial layer 275-1 may cause defects and/or undesired amounts and/or types of stress in multilayer stack 160A during formation thereof. In some embodiments, thickness t2 and/or a composition of release layer 250A-1 is configured to provide a lattice mismatch between release layer 250A-1 and multilayer stack 160A (e.g., semiconductor layer 162 thereof) and/or sacrificial layer 275-1 that is comparable to a lattice mismatch between substrate 140A and multilayer stack 160A (e.g., semiconductor layer 162 thereof) and/or sacrificial layer 275-1. For example, referring again to FIG. 6C, forming release layer 250A-1 using oxygen treatment OT1 (which inserts oxygen into substrate 140A) and having a thickness less than about 20 nm minimizes lattice mismatch between substrate 140A and a semiconductor layer, such as sacrificial layer 275-1 and/or semiconductor layer 162, formed thereon. As depicted in FIG. 6C, substrate 140A may have a silicon lattice, and sacrificial layer 275-1 may have a silicon lattice. Because release layer 250A-1 may be formed by oxygen covalently bonded interstitially into a portion of the silicon lattice of substrate 140A, minimal lattice mismatch is between release layer 250A-1 and sacrificial layer 275-1. The depicted process flow thus enables damage-free release of substrate 140A while facilitating high-quality deposition/growth thereon/thereover, such as high-quality epitaxial growth.

Referring to FIG. 6H, sacrificial layer 275-1 is removed from stacked structure 170-1 (e.g., multilayer stack 160A thereof) by any suitable process. For example, a planarization process, such as CMP, is performed to remove sacrificial layer 275-1. After bonding and removal of substrate 140A and release layer 250A-1 by laser treatment and sacrificial layer 275-1 (e.g., by CMP), stacked structure 170-1 includes device component A (including multilayer stack 160A, but no longer including substrate 140A, release layer 250A-1, and sacrificial layer 275-1), device component B (including multilayer stack 160B and substrate 140B), and bonding structure 172-1 therebetween, such as described above with reference to FIG. 3G.

Referring to FIG. 6I, substrate 140A may be reused to prepare and/or provide other stacked structures, such as stacked structure 170-2. For example, substrate 140A may form a portion of another device component, such as device component C, multilayer stack 160C is formed over substrate 140A, and device component D is received and/or formed for stacking with device component C (such as described above with reference to FIG. 3H). In the depicted embodiment, since release layer 250A-1 is removed by the laser treatment, a release layer 250A-2 may be formed on and/or in substrate 140A before forming multilayer stack 160C. Further, a sacrificial layer 275-2 may be formed over release layer 250A-2, such that sacrificial layer 275-2 is disposed between sacrificial layer 250A-2 and multilayer stack 160C. Release layer 250A-2 may be configured the same as and/or different than release layer 250A-1, and release layer 250A-2 may be configured as and/or include any of the materials described above with reference to release layer 250A-1. Sacrificial layer 275-2 may be configured the same as and/or different than sacrificial layer 275-1, and sacrificial layer 275-2 may be configured as and/or include any of the materials described above with reference to sacrificial layer 275-1.

Referring to FIG. 6J and FIG. 6K, device component C may be bonded and/or attached to device component D, such as described above with reference to FIG. 6E and FIG. 6F, to provide stacked structure 170-2. In FIG. 6K, stacked structure 170-2 includes release layer 250A-2 and sacrificial layer 275-2 between multilayer stack 160C and substrate 140A of device component C. Referring to FIG. 6L, substrate 140A and release layer 250A-2 are removed from stacked structure 170-2 by laser treatment, such as described above with reference to FIG. 6G. In the depicted embodiment, substrate 140A and release layer 250A-1 are removed from sacrificial layer 275-2, instead of multilayer stack 160C. Inserting sacrificial layer 275-2 between release layer 250A-2 and multilayer stack 160C provides additional protection to multilayer stack 160C during removal of substrate 140A. Referring to FIG. 6M, sacrificial layer 275-2 may be removed from stacked structure 170-2 (e.g., multilayer stack 160C thereof), such as described above with reference to FIG. 6H. For example, sacrificial layer 275-2 is removed by CMP. After removal of substrate 140A from stacked structure 170-2, substrate 140A may be reused again multiple times. The process flow of FIGS. 6A-6M thus enables multiple uses of a single carrier substrate (and release layer), which significantly reduces fabrication costs.

FIGS. 7A-7M illustrate yet another process flow, in portion or entirety, for preparing stacked structures, according to various aspects of the present disclosure. The process flow illustrated in FIGS. 7A-7M implements a debonding technique that enables reuse of a carrier substrate, such as illustrated in FIG. 4, thereby reducing costs associated with fabricating devices. In some embodiments, the process flow may be implemented to prepare stacked precursors, which may be processed to form stacked device structures, such as stacked device structure 10A and/or stacked device structure 10B. Since the process flow depicted in FIGS. 7A-7M is similar in many respects to the process flow depicted in FIGS. 6A-6M, similar features are identified by the same reference numerals for clarity and simplicity. FIGS. 7A-7M have been simplified for the sake of clarity to better understand the inventive concepts of the present disclosure. Additional steps may be provided before, during, and after the various process steps depicted in FIGS. 7A-7M, and some of the steps described may be moved, replaced, or eliminated for additional embodiments of the process flow depicted in FIGS. 7A-7M. Further, additional features may be added in FIGS. 7A-7M, and some of the features described may be replaced, modified, or eliminated in other embodiments of FIGS. 7A-7M.

Referring to FIG. 7A, substrate 140A is provided for device component A, such as described above with reference to FIG. 6A. Referring to FIG. 7B, a release layer 250B-1, instead of release layer 250A-1, having a thickness t3 is formed on and/or in substrate 140A. In the depicted embodiment, an oxygen treatment OT2 is performed that introduces oxygen to and/or into a portion of substrate 140A over which multilayer stack 160A is subsequently formed. In some embodiments, oxygen treatment OT2 implants oxygen into a portion of substrate 140A, thereby providing substrate 140A with an oxygen-implanted region, which is referred to as release layer 250B-1. Where first substrate 140A is a semiconductor substrate, oxygen treatment OT2 may provide substrate 140A with an oxygen-doped (and/or oxygen-implanted) semiconductor region (i.e., release layer 250B-1). The oxygen-doped semiconductor region may be referred to as a semiconductor oxide region. In some embodiments, substrate 140A is a silicon substrate, and oxygen treatment OT2 provides substrate 140A with an oxygen-doped silicon region. In such embodiments, release layer 250B-1 is the oxygen-doped silicon region, which may also be referred to as a silicon oxide region and/or a silicon oxide layer of and/or over substrate 140A. In some embodiments, oxygen treatment OT2 further implants carbon into the portion of substrate 140A. In such embodiments, release layer 250B-1 may be an oxygen-and-carbon doped semiconductor region, such as an oxygen-and-carbon doped silicon region, of substrate 140A. In some embodiments, oxygen treatment OT2 is an implantation process that dopes substrate 140A with oxygen. In some embodiments, oxygen treatment OT2 is an implantation process that dopes substrate 140A with both oxygen and carbon (e.g., oxygen treatment OT2 may be a co-implantation process). Since oxygen-doped semiconductor region is a shallow doped region (i.e., formed in an upper portion of substrate 140A with thickness t3, which may be less than about 20 nm as described below), incorporating carbon into the implantation process may improve control of a profile of the oxygen-doped semiconductor region. In some embodiments, parameters of the implantation process, such as implant energy, implant dopant type (e.g., adding carbon), implant dosage, implant angle, other suitable implant parameter, or combinations thereof are tuned to provide release layer 250B-1 with thickness t3 at a surface of substrate 140A over which multilayer stack 160A is formed. In some embodiments, oxygen treatment OT2 includes performing an annealing process, such as a rapid thermal anneal or a laser anneal, after the oxygen doping/implantation process.

Substrate 140A and oxygen treatment OT2 are configured to provide device component A with a release layer, such as release layer 250B-1 (e.g., semiconductor oxide, such as silicon oxide), that facilitates adhesion and/or attachment of a material layer(s) to substrate 140A and/or release layer 250B-1, yet enables removal of substrate 140A by laser treatment, as described below. For example, substrate 140A is formed of a material that is transparent to, and thus transmits, IR radiation, while release layer 250B-1 is formed of a material that absorbs IR radiation to enable release of substrate 140A. In some embodiments, substrate 140A transmits wavelengths of IR radiation of about 1 μm to about 10 μm. In some embodiments, release layer 250B-1 transmits smaller wavelengths of IR radiation than substrate 140A, such as wavelengths of IR radiation of about 0.2 μm to about 4 μm. As another example, a CTE of release layer 250B-1 is greater than a CTE of first substrate 140A. The greater CTE of release layer 250B-1 may enhance ablation thereof, and thus, efficiency of the laser treatment. In some embodiments, the CTE of release layer 250B-1 (e.g., silicon oxide) is about 7×10⁻⁶ K⁻¹. In some embodiments, the CTE of substrate 140A (e.g., silicon substrate) is about 2.6×10⁻⁶ K⁻¹.

Referring to FIG. 7C, multilayer stack 160A is formed on substrate 140A, such as described above with reference to FIG. 6C. In the process flow of FIGS. 7A-7M, to further protect multilayer stack 160A from damage during removal of substrate 140A, sacrificial layer 275-1 may be formed over release layer 250B-1 before forming multilayer stack 160A, such as described above with reference to FIG. 6C. Referring to FIG. 7D, device component B is received and/or formed for stacking with device component A, such as described above with reference to FIG. 6D. Referring to FIG. 7E and FIG. 7F, stacked structure 170-1 is formed by bonding and/or attaching device component A and device component B, such as described above with reference to FIG. 6E and FIG. 6F. In the depicted embodiment, device component A of stacked structure 170-1 includes release layer 250B-1, instead of release layer 250A-1, and sacrificial layer 275-1 between substate 140A and multilayer stack 160A.

Referring to FIG. 7G, substrate 140A and release layer 250B-1 are removed from stacked structure 170-1 by laser treatment, such as described above with reference to FIG. 6G. For example, IR radiation from IR laser beam 278 penetrates through substrate 140A to release layer 250B-1, and release layer 250B-1 absorbs the IR radiation. As release layer 250B-1 absorbs the IR radiation and reaches its ablation threshold, substrate 140A is released from device component A. In the depicted embodiment, substrate 140A and release layer 250B-1 are removed and/or released from sacrificial layer 275-1. In some embodiments, various laser process parameters (e.g., wavelength of the IR radiation, a duration of IR laser pulses, a number of IR laser pulses, parameters of an environment of stacked structure 170-1 during the laser treatment (e.g., temperature, pressure, ambient, etc.), or combinations thereof) are configured to efficiently and quickly reach the ablation threshold of release layer 250B-1. In some embodiments, release layer 250B-1 may decompose as heated by the IR radiation, thereby enabling release of substrate 140A. In some embodiments, the laser treatment breaks down and/or vaporizes release layer 250B-1 as release layer 250B-1 is exposed thereto, thereby enabling release of substrate 140A. In the depicted embodiment, the laser treatment may weaken bonding and/or attachment of release layer 250B-1 and sacrificial layer 275-1 (and/or multilayer stack 160A), enabling release of substrate 140A, but not completely abate release layer 250B-1. Release layer 250B-1, or portion thereof, may thus remain after the laser treatment, such as depicted in FIG. 7G. Such may result from differences in compositions, bonding mechanisms, lattice structures, or other characteristics of release layer 250B-1 and release layer 250A-1.

A wavelength of IR radiation emitted by IR laser beam 278 is configured such that the IR radiation transmits through substrate 140A, but not release layer 250B-1 (i.e., the wavelength of the IR radiation is configured such that at least a portion of the IR radiation is absorbed by release layer 250B-1). In some embodiments, IR laser beam 278 emits IR radiation with a wavelength greater than about 4 μm, such as about 4 μm to about 10 μm. Release layer 250B-1 may not absorb IR radiation having a wavelength less than 4 μm, such that an ablation threshold of release layer 250B-1 may not be reached when exposed to IR radiation having wavelengths less than 4 μm, thereby impeding and/or preventing release of substrate 140A. Further, substrate 140A may block IR radiation having a wavelength greater than 10 μm, such that IR radiation having wavelengths greater than 10 μm may not reach release layer 250B-1, thereby impeding and/or preventing release of substrate 140A.

Thickness t3 is configured to minimize an impact of release layer 250B-1 on formation of multilayer stack 160A on substrate 140A (e.g., by minimizing lattice mismatch) and/or enable sufficient absorption of the IR radiation by release layer 250B-1, such that substrate 140A may be removed from multilayer stack 160A (e.g., by laser treatment) with minimal to no damage thereto. For example, if release layer 250B-1 is too thin (e.g., t3 is less than 1 nm), release layer 250B-1 may not absorb enough of the IR radiation during the laser treatment to facilitate release of substrate 140A. If release layer 250B-1 is too thick (e.g., t3 is greater than 20 nm), a lattice mismatch between release layer 250-1 and multilayer stack 160A (e.g., semiconductor layer 162 thereof) and/or sacrificial layer 275-1 may cause defects and/or undesired amounts and/or types of stress in multilayer stack 160A during formation thereof. In some embodiments, thickness t3 and/or a composition of release layer 250B-1 is configured to provide a lattice mismatch between release layer 250B-1 and multilayer stack 160A (e.g., semiconductor layer 162 thereof) and/or sacrificial layer 275-1 that is comparable to a lattice mismatch between substrate 140A and multilayer stack 160A (e.g., semiconductor layer 162 thereof) and/or sacrificial layer 275-1. For example, referring again to FIG. 7C, forming release layer 250B-1 using oxygen treatment OT2 (which implants oxygen into substrate 140A) and having a thickness less than about 20 nm minimizes lattice mismatch between substrate 140A and a semiconductor layer, such as sacrificial layer 275-1 and/or semiconductor layer 162, formed thereon. As depicted in FIG. 7C, substrate 140A may have a silicon lattice, and sacrificial layer 275-1 may have a silicon lattice. Because release layer 250B-1 may be formed by oxygen covalently bonded interstitially into a portion of the silicon lattice of substrate 140A, minimal lattice mismatch is between release layer 250B-1 and sacrificial layer 275-1. The depicted process flow thus enables damage-free release of substrate 140A while facilitating high-quality deposition/growth thereon/thereover, such as high-quality epitaxial growth.

Referring to FIG. 7H, sacrificial layer 275-1 is removed from stacked structure 170-1, such as described above with reference to FIG. 6H. Referring to FIG. 7I, substrate 140A may be reused to prepare and/or provide other stacked structures, such as stacked structure 170-2, such as described above with reference to FIG. 6I. In the depicted embodiment, since the laser treatment may not remove, or only partially remove, release layer 250B-1, any remainder of release layer 250B-1 may be removed before reusing substrate 140A. For example, release layer 250B-1 is removed from substrate 140A by a planarization process (e.g., CMP) and/or other suitable process. After removing release layer 250B-1, a release layer 250B-2 may be formed on and/or in substrate 140A, and sacrificial layer 275-2 may be formed over release layer 250B-2, before forming multilayer stack 160C. Release layer 250B-2 may be configured the same as and/or different than release layer 250B-1, and release layer 250B-2 may be configured as and/or include any of the materials described above with reference to release layer 250B-1.

Referring to FIG. 7J and FIG. 7K, device component C may be bonded and/or attached to device component D, such as described above with reference to FIG. 6J and FIG. 6K, to provide stacked structure 170-2. In FIG. 7K, stacked structure 170-2 includes release layer 250B-2 and sacrificial layer 275-2 between multilayer stack 160C and substrate 140A of device component C. Referring to FIG. 7L, substrate 140A and release layer 250B-2 are removed from stacked structure 170-2 by laser treatment, such as described above with reference to FIG. 7G. In the depicted embodiment, substrate 140A and release layer 250B-2 are removed from sacrificial layer 275-2, instead of multilayer stack 160C. Referring to FIG. 7M, sacrificial layer 275-2 may be removed from stacked structure 170-2 (e.g., multilayer stack 160C thereof), such as described above with reference to FIG. 7H. After removal of substrate 140A from stacked structure 170-2 (and, in some embodiments, after removal of release layer 250B-2 from substrate 140A), substrate 140A may be reused again. The process flow of FIGS. 7A-7M thus enables multiple uses of a single carrier substrate, which significantly reduces fabrication costs.

In some embodiments, sacrificial layers, such as sacrificial layer 275-1 and sacrificial layer 275-2, may be omitted from the process flows depicted in FIGS. 6A-6M and/or FIGS. 7A-7M. For example, FIGS. 8A-8K illustrate yet another process flow, in portion or entirety, for preparing stacked structures, according to various aspects of the present disclosure. The process flow illustrated in FIGS. 8A-8K implements a debonding technique that enables reuse of a carrier substrate, such as illustrated in FIG. 4, thereby reducing costs associated with fabricating devices. In some embodiments, the process flow may be implemented to prepare stacked precursors, which may be processed to form stacked device structures, such as stacked device structure 10A and/or stacked device structure 10B. Since the process flow depicted in FIGS. 8A-8K is similar in many respects to the process flows depicted in FIGS. 6A-6M and/or FIGS. 7A-7M, similar features are identified by the same reference numerals for clarity and simplicity. In the process flow of FIGS. 8A-8K, sacrificial layer 275-1 and sacrificial layer 275-2 are omitted, such that multilayer stack 160A is formed directly on release layer of substrate 140A (e.g., release layer 250A-1 or release layer 250B-1) (FIG. 8C), substrate 140A is released form multilayer stack 160A (FIG. 8G), multilayer stack 160C is formed directly on release layer of substrate 140A (e.g., release layer 250A-2 or release layer 250B-2) (FIG. 8H), and substrate 140A is released form multilayer stack 160C (FIG. 8K). Further, processing related to removing sacrificial layer 275-1 and sacrificial layer 275-2 may be omitted from preparation of stacked structure 170-1 and stacked structure 170-2, respectively. FIGS. 8A-8K have been simplified for the sake of clarity to better understand the inventive concepts of the present disclosure. Additional steps may be provided before, during, and after the various process steps depicted in FIGS. 8A-8K, and some of the steps described may be moved, replaced, or eliminated for additional embodiments of the process flow depicted in FIGS. 8A-8K. Further, additional features may be added in FIGS. 8A-8K, and some of the features described may be replaced, modified, or eliminated in other embodiments of FIGS. 8A-8K.

FIGS. 9A-9F are cross-sectional views of stacked device structure 10A, in portion or entirety, at various monolithic fabrication stages, according to various aspects of the present disclosure. FIGS. 9A-9F have been simplified for the sake of clarity to better understand the inventive concepts of the present disclosure. Additional steps may be provided before, during, and after the monolithic fabrication steps of FIGS. 9A-9F, and some of the steps described may be moved, replaced, or eliminated for additional embodiments of the monolithic fabrication steps of FIGS. 9A-9F. Additional features may be added in stacked device structure 10A of FIGS. 9A-9F, and some of the features described below may be replaced, modified, or eliminated in other embodiments of stacked device structure 10A of FIGS. 9A-9F.

Referring to FIG. 9A, fabricating stacked device structure 10A includes receiving and/or preparing a stacked device precursor, such as stacked structure 170-1. Stacked structure 170-1 may provide a device precursor for device 12L (e.g., multilayer stack 160B and substrate 140B) attached and/or bonded to a device precursor for device 12U (e.g., multilayer stack 160A). The device precursor of device 12L may be attached to the device precursor of device 12U, and electrically isolated from the device precursor of device 12U, by insulation/isolation/bonding structure 172-1, which includes insulation/bonding layer 172A and insulation/bonding layer 172B. Accordingly, at this stage of processing, insulation/bonding structure 172-1 provides isolation structure 16A of stacked device structure 10A, which electrically isolates and separates device 12L and device 12U. In some embodiments, a thickness of insulation/bonding structure 172-1 is about 10 nm to about 50 nm. Stacked structure 170-1 may be prepared by any of the process flows described above, such as those depicted in FIGS. 3A-3K, FIG. 4, FIGS. 5A-5J, FIGS. 6A-6M, FIGS. 7A-7M, FIGS. 8A-8K, or combinations thereof.

Referring to FIGS. 9B-9F, fabricating stacked device structure 10A includes processing the device precursors to form device 12L and device 12U. Referring to FIG. 9B, a fin fabrication process may be performed to form fins 310 (also referred to as fin structures, fin elements, etc.) extending from substrate 140B (which provide substrate 14 of stacked device structure 10A). Fins 310 extend substantially parallel to one another along an x-direction, having a length in the x-direction, a width in a y-direction, and a height in a z-direction. Each of fins 310 include a substrate portion (e.g., a respective protrusion 140B′ (which provide respective protrusions 14′ of stacked device structure 10A), a lower multilayer stack portion disposed over the substrate portion (e.g., a respective portion of multilayer stack 160B), an isolation portion disposed over the lower multilayer stack portion (e.g., a respective portion of insulation structure 172-1), and an upper multilayer stack portion (e.g., a respective portion of multilayer stack 160A) disposed over the isolation portion. Fabrication of fins 310 may include performing a lithography process and/or etching process to pattern a semiconductor layer stack precursor (e.g., stacked structure 170-1). In some embodiments, fins 310 are formed by a multiple patterning process, such as a double patterning lithography (DPL) process (for example, a lithography-etch-lithography-etch (LELE) process, a self-aligned double patterning (SADP) process, a spacer-is-dielectric (SID) SADP process, other double patterning process, or combinations thereof), a triple patterning process (for example, a lithography-etch-lithography-etch-lithography-etch (LELELE) process, a self-aligned triple patterning (SATP) process, other triple patterning process, or combinations thereof), other multiple patterning process (for example, a self-aligned quadruple patterning (SAQP) process), or combinations thereof.

Referring to FIG. 9C, fabricating stacked device structure 10A includes forming substrate isolation structures 315 in trenches between fins 310. Substrate isolation structures 315 may fill lower portions of the trenches between fins 310 and may surround lower portions of fins 310. Substrate isolation structures 315 electrically isolate active device regions (e.g., fins 310) and/or passive device regions. Substrate isolation structures 315 include silicon oxide, silicon nitride, silicon oxynitride, other suitable isolation material (including, for example, silicon, oxygen, nitrogen, carbon, other suitable isolation constituent, etc.), or combinations thereof. Substrate isolation structures 315 may have a multilayer structure. For example, substrate isolation structures 315 include a bulk dielectric (e.g., an oxide layer) over a dielectric liner (for example, silicon nitride, silicon oxide, silicon oxynitride, silicon oxycarbonitride, or combinations thereof). In another example, substrate isolation structures 315 include a bulk dielectric over a doped liner, such as a boron BSG liner and/or a PSG liner. Dimensions and/or characteristics of substrate isolation structures 315 are configured to provide shallow trench isolation (STI) structures, deep trench isolation (DTI) structures, local oxidation of silicon (LOCOS) structures, other suitable isolation structures, or combinations thereof.

Referring to FIG. 9D, fabricating stacked device structure 10A may include forming dummy gate stacks 330 over portions of fins 310, forming gate spacers 44 along sidewalls of dummy gate stacks 330, and forming source/drain recesses 335. Dummy gate stacks 330 extend lengthwise in a direction that is different than (e.g., orthogonal to) the lengthwise direction of fins 310. For example, dummy gate stacks 330 extend along the y-direction, having a length in the y-direction, a width in the x-direction, and a height in the z-direction. In the X-Z plane, dummy gate stacks 330 are disposed over tops of channel regions (C) of fins 310 and/or stacked device structure 10A, and dummy gate stacks 330 are disposed between source/drain regions (S/D) of fins 310 and/or stacked device structure 10A. In the Y-Z plane, dummy gate stacks 330 may be disposed on tops and sidewalls of fins 310, and dummy gate stacks 330 may wrap channel regions. Dummy gate stacks 330 may include a dummy gate dielectric, a dummy gate electrode, a hard mask, other suitable layers, or combinations thereof. The dummy gate dielectric includes a dielectric material, such as silicon oxide and/or other suitable dielectric material. The dummy gate electrode includes any suitable dummy gate material, such as polysilicon. The hard mask includes any suitable hard mask material, such as silicon nitride.

Source/drain recesses 335 may be formed by performing an etching process that removes multilayer stack 160A, insulation structure 172-1, and multilayer stack 160B in source/drain regions of fins 310, thereby exposing protrusions 140B′ (14′). The etching process further removes some, but not all, of protrusions 140B′ (14′), such that source/drain recesses 335 may extend below top surfaces of substrate isolation structures 315. Each source/drain recess 335 has respective sidewalls formed by respective remaining portions of multilayer stack 160A, insulation structure 172-1, and multilayer stack 160B in channel regions of fins 310 and a bottom formed by a respective protrusion 140B′ (14′). In the depicted embodiment, after forming source/drain recesses 335, each channel region includes an upper channel portion 340U (e.g., formed by a remaining portion of multilayer stack 160A) and a lower channel portion 340L (e.g., formed by a remaining portion of multilayer stack 160B) separated by a channel isolation structure (e.g., isolation structure 17A, which is formed by a remaining portion of insulation structure 172-1). In some embodiments, the etching process removes some, but not all, of multilayer stack 160B, and source/drain recesses 335 have bottoms formed by semiconductor layers 162 or semiconductor layers 164. In some embodiments, the etching process stops at protrusion 140B′ (14′), and source/drain recesses 335 do not extend below substrate isolation structures 315. The etching process is a dry etch, a wet etch, other suitable etch, or combinations thereof. In some embodiments, the etching process is a multistep etch process.

Referring to FIG. 9E, fabricating stacked device structure 10A may include forming inner spacers 54 under gate spacers 44 along sidewalls of semiconductor layers 162. Inner spacers 54 replace portions of semiconductor layers 162 under gate spacers 44, separate semiconductor layers 164 from one another, and separate bottom semiconductor layers 164 from protrusions 140B′ (14′). Forming inner spacers 54 may include a first etching process, a deposition process, and a second etching process. The first etching process selectively etches semiconductor layers 162 with negligible etching of semiconductor layers 164 and protrusions 140B′ (14′). The first etching process is configured to laterally etch semiconductor layers 162 to reduce lengths thereof along the x-direction, thereby forming gaps between semiconductor layers 164 and between protrusions 140B′ (14′) and semiconductor layers 164 that separate adjacent semiconductor layers 164 and separate protrusions 140B′ (14′) and adjacent semiconductor layers 164. In some embodiments, the gaps laterally extend under dummy gate stacks 330. The deposition process forms a spacer layer that at least partially fills (and may completely fill) the gaps, and the second etching process selectively etches the spacer layer with negligible etching of semiconductor layers 164 and protrusions 140B′ (14′), such that remainders of the spacer layer form inner spacers 54. In some embodiments, the spacer layer (and thus inner spacers 54) includes a dielectric material that includes silicon, oxygen, carbon, nitrogen, other suitable dielectric constituent, or combinations thereof. For example, the spacer layer is a silicon nitride layer, a silicon carbonitride layer, a silicon oxycarbonitride layer, a silicon oxycarbide layer, or combinations thereof. In some embodiments, fabrication of inner spacers 54 is configured to provide inner spacers 54 with a multilayer structure and/or air gaps.

Referring to FIG. 9E, fabricating stacked device structure 10A may further include forming source/drain stacks in source/drain recesses 335 and forming a dielectric layer (e.g., CESL 70U and ILD layer 72U) over the source/drain stacks. Each source/drain stack includes a respective source/drain 62U and a respective source/drain 62L separated by a respective source/drain isolation structure, such as isolation structure 18 (e.g., CESL 70L and ILD layer 72L). Source/drain stacks may be formed by filling a bottom/lower portion of source/drain recesses 335 with one or more epitaxial semiconductor materials to form source/drains 62L adjacent to semiconductor layers 164 of channel portion 340L, filling a middle portion of source/drain recesses 335 with one or more dielectric materials (e.g., CESL 70L and ILD layer 72L) to form isolation structures 18 adjacent to isolation structures 17A (i.e., channel isolation structures), and filling a top/upper portion of source/drain recesses 335 with one or more epitaxial semiconductor materials to form source/drains 62U adjacent to semiconductor layers 164 of channel portion 340U. Semiconductor layers 164 extending between source/drains 62U may provide upper semiconductor layers 26U of stacked device structure 10A, semiconductor layers 164 extending between source/drains 62L may provide lower semiconductor layers 26L of stacked device structure 10A, and semiconductor layers 164 extending between isolation structures 18 may provide middle semiconductor layers 26M of stacked device structure 10A. In the depicted embodiment, which is directed to stacked device structure 10A being fabricated from stacked structure 170-1, stacked device structure 10A does not include middle semiconductors 26M. Source/drains 62L and source/drains 62U are formed by any suitable process, such as an epitaxial deposition and/or growth process. Isolation structures 18 may be formed by depositing a CESL over source/drains 62L, depositing an ILD layer over the CESL, and etching back the CESL and/or the ILD layer to expose semiconductor layers 164 of channel portion 340U that will provide channels for device 12U (e.g., semiconductor layers 26U).

In the depicted embodiment, isolation structure 16A, which separates and/or electrically isolates device 12L and device 12U, is provided by isolation structures 17A (i.e., channel isolation structures and/or gate isolation structures) and isolation structures 18 (i.e., source/drain isolation structures), and isolation structures 17A are formed by insulation/bonding structure 172-1, which may include insulation/bonding layer 172A and insulation/bonding layer 172B. Isolation structures 17A are between isolation structures 18. In the depicted embodiment, a thickness of isolation structures 18 (e.g., along the z-direction) is greater than a thickness of isolation structures 17A. The present disclosure contemplates other configurations of isolation structures 17A and isolation structures 18, such as where a thickness of isolation structures 18 is substantially the same as a thickness of isolation structures 17A.

Referring to FIG. 9F, fabricating stacked device structure 10A may include performing a gate replacement process to replace dummy gate stacks 330 with gates and performing a channel release process to form suspended channel layers in channel regions. In some embodiments, fabrication includes removing dummy gate stacks 330 to form gate openings (e.g., by a selective etching process); removing semiconductor layers 162 exposed by the gate openings to form gaps/openings between semiconductor layers 164 (26U, 26L), between semiconductor layers (26U, 26L) and isolation structures 17A, and between semiconductor layers (26L) and protrusions 140B′ (14′) (e.g., by a selective etching process), thereby suspending semiconductor layers 164 (26U, 26L) over protrusions 140B′ (14′); and forming gates 90 that fill the gate openings and the gaps. Each gate 90 may include a respective gate 90L (e.g., a respective gate dielectric 78L and a respective gate electrode 80L) and a respective gate 90U (e.g., a respective gate dielectric 78U and a respective gate electrode 80U). Gate 90L is separated from gate 90U by a respective isolation structure 17A. In some embodiments, gate 90L is separated from gate 90U by isolation structure 17A and middle, dummy semiconductor layers (e.g., semiconductor layers 26M). In the depicted embodiment, each channel region has two upper semiconductor layers 164, which may be referred to as channel (or semiconductor) layers 26U, and two lower semiconductor layers 164, which may be referred to as lower channel (or semiconductor) layers 26L. Channel layers 26U are vertically stacked along the z-direction and provide two channels for transistor 20U through which current may flow between source/drains 62U. Channel layers 26L are vertically stacked along the z-direction and provide two channels for transistor 20L through which current may flow between source/drains 62L.

In some embodiments, gates 90U are recessed and/or etched back, such that top surfaces of gates 90U are lower than top surface of ILD layer 72U, and hard masks 92 (which may be referred to as self-aligned contact (SAC) features/structures) are formed over gates 90U. Hard masks 92 include a material that is different than ILD layer 72U and/or subsequently formed ILD layers to achieve etch selectivity during subsequent etching processes. In some embodiments, hard masks 92 include silicon and nitrogen and/or carbon, such as silicon nitride, silicon oxynitride, silicon carbide, silicon oxycarbide, silicon carbonitride, silicon oxycarbonitride, other silicon nitride, other silicon carbide, or combinations thereof. In some embodiments, hard masks 92 include metal and oxygen and/or nitrogen, such as aluminum oxide (e.g., AlO or Al₂O₃), aluminum nitride (e.g., AlN), aluminum oxynitride (e.g., AlON), zirconium oxide, zirconium nitride, hafnium oxide (e.g., HfO or HFO₂), zirconium aluminum oxide (e.g., ZrAlO), other metal oxide, other metal nitride, or combinations thereof. In some embodiments, hard masks 92 include an amorphous semiconductor material, such as amorphous silicon. In some embodiments, hard masks 92 are formed by depositing a hard mask material that fills recesses formed over gates 90U (e.g., recesses having sidewalls formed by gate spacers 44 and bottoms formed by recessed gates 90U) and planarizing the hard mask material.

In some embodiments, fabricating stacked device structure 10A may further include forming interconnects, such as gate contacts and/or source/drain contacts. For example, upper source/drain contacts may be formed in the dielectric layer (e.g., ILD layer 72U and/or CESL 70U) on source/drains 62U and lower source/drain contacts may be formed on source/drains 62L. In some embodiments, a source/drain via may be formed that electrically connects a respective source/drain 62U and a respective source/drain 62U. In such embodiments, the source/drain via may be physically and/or electrically connected to an upper source/drain contact formed on the respective source/drain 62U and a lower source/drain contact formed on the respective source/drain 62L. Forming the source/drain contacts may include forming source/drain contact openings in the dielectric layer (or substrate 140B (14)) that expose source/drains 62U (or source/drains 62L) and forming at least one electrically conductive layer in the source/drain contact openings. In some embodiments, forming the source/drain contact openings includes forming a patterned mask layer (e.g., an etch mask) over the dielectric layer (or substrate) and etching exposed portions of the dielectric layer (or substrate). In some embodiments, forming at least one electrically conductive layer in the source/drain contact openings includes forming metal silicide layers over the epitaxial source/drains, depositing a barrier/liner layer that partially fills the source/drain contact openings, depositing a metal layer over the barrier/liner layer that fills remainders of the source/drain contact openings, and performing a planarization process to remove portions of the barrier/liner layer and/or the metal layer that are disposed over the tops of the dielectric layer and/or the gate structures. A source/drain contact may thus include a metal silicide layer, a barrier/liner layer, and a bulk metal layer, where the barrier/liner layer is between the bulk metal layer and the dielectric layer (or substrate) and the bulk metal layer and the metal silicide layer. In some embodiments, one or more insulation layers may be formed in the source/drain contact openings and processed to form contact spacers, such as dielectric layers and/or air gaps, which may be disposed along sidewalls of electrically conductive portions of the source/drain contacts.

In embodiments where stacked structures are provided for sequentially fabricating a stacked transistor, device component B (and/or device component D) may be a first device (e.g., a lower transistor), and device component A (and/or device component C) may be is a device precursor (e.g., multilayer stack 160A or multilayer stack 160C) for fabricating a second device (e.g., an upper transistor). After bonding, the second precursor may be processed to form the second device over the first device, and a bonding/insulation structure (e.g., bonding structure 172-1 or bonding structure 172-2) may provide an isolation structure, such as isolation structure 17B of isolation structure 16B, between the first device and the second device.

FIGS. 10A-10D are cross-sectional views of stacked device structure 10B, in portion or entirety, at various sequential fabrication stages, according to various aspects of the present disclosure. FIGS. 10A-10D have been simplified for the sake of clarity to better understand the inventive concepts of the present disclosure. Additional steps may be provided before, during, and after the sequential fabrication steps of FIGS. 10A-10D, and some of the steps described may be moved, replaced, or eliminated for additional embodiments of the sequential fabrication steps of FIGS. 10A-10D. Additional features may be added in stacked device structure 10B of FIGS. 10A-10D, and some of the features described below may be replaced, modified, or eliminated in other embodiments of stacked device structure 10B of FIGS. 10A-10D.

Referring to FIG. 10A, fabricating stacked device structure 10B includes receiving and/or preparing a stacked device precursor, such as stacked structure 170-1. When implemented for sequential fabrication, stacked structure 170-1 may provide a device (e.g., device 12L) attached and/or bonded to a device precursor for device 12U (e.g., multilayer stack 160A). Device 12L may be attached to the device precursor of device 12U, and electrically isolated from the device precursor of device 12U, by insulation/isolation/bonding structure 172-1, which includes insulation/bonding layer 172A and insulation/bonding layer 172B. Accordingly, at this stage of processing, insulation/bonding structure 172-1 provides isolation structure 16B of stacked device structure 10B, which electrically isolates and separates device 12L and device 12U. In some embodiments, a thickness of insulation/bonding structure 172-1 is about 10 nm to about 50 nm. Stacked structure 170-1, such as depicted in FIG. 10A, may be prepared by any of the process flows described above, such as those depicted in FIGS. 3A-3K, FIG. 4, FIGS. 5A-5J, FIGS. 6A-6M, FIGS. 7A-7M, FIGS. 8A-8K, or combinations thereof.

Referring to FIGS. 10B-10D, fabricating stacked device structure 10B may include processing the device precursor to form device 12U. Referring to FIG. 10B, processing the device precursor may include patterning multilayer stack 160A to form fins 410 extending from isolation structure 16B (such as described above with reference to FIG. 9B), forming dummy gate stacks 430 over portions of fins 410 (such as described above with reference to FIG. 9C), forming gate spacers 44U along sidewalls of dummy gate stacks 430 (such as described above with reference to FIG. 9C), and forming source/drain recesses 435 (such as described above with reference to FIG. 9B). Dummy gate stacks 430 extend lengthwise in a direction that is different than (e.g., orthogonal to) the lengthwise direction of fins 410. For example, dummy gate stacks 430 extend along the y-direction, having a length in the y-direction, a width in the x-direction, and a height in the z-direction. In the X-Z plane, dummy gate stacks 430 are disposed over tops of channel regions (C) of fins 410 and/or stacked device structure 10B, and dummy gate stacks 430 are disposed between source/drain regions (S/D) of fins 410 and/or stacked device structure 10B. In the Y-Z plane, dummy gate stacks 430 may be disposed on tops and sidewalls of fins 410, and dummy gate stacks 430 may wrap channel regions. Dummy gate stacks 430 may be similar to dummy gate stacks 330, such as described above with reference to FIG. 9C. For example, dummy gate stacks 430 may include a dummy gate dielectric, a dummy gate electrode, a hard mask, other suitable layers, or combinations thereof.

Source/drain recesses 435 may be formed by performing an etching process that removes multilayer stack 160A in source/drain regions of fins 410, thereby exposing insulation/bonding structure 172-1 (16B) (e.g., insulation/bonding layer 172A thereof). Each source/drain recess 435 has respective sidewalls formed by respective remaining portions of multilayer stack 160A in channel regions of fins 410 and a bottom formed by insulation layer 172A. In the depicted embodiment, after forming source/drain recesses 435, each channel region has a channel portion 440 formed by a respective remainder of multilayer stack 160A. Channel portion 440 is separated from a channel portion/gate portion of device 12L by bonding/isolation structure 172-1. The etching process is a dry etch, a wet etch, other suitable etch, or combinations thereof. In some embodiments, the etching process is a multistep etch process.

Referring to FIG. 10C, fabricating stacked device structure 10B may include forming inner spacers 54U under gate spacers 44U along sidewalls of semiconductor layers 162, such as described above with reference to FIG. 9E; forming source/drains 62U in source/drain recesses 435, such as described above with reference to FIG. 9E; and forming a dielectric layer (e.g., CESL 70U and ILD layer 72U) over source/drains 62U, such as described above with reference to FIG. 9E. Source/drains 62U are disposed vertically over source/drains 62L, and source/drains 62U may be electrically isolated from source/drains 62L and/or source/drain contacts thereto by insulation/bonding structure 172-1 (which provides isolation structure 16B). Semiconductor layers 164 extending between source/drains 62U may be referred to as upper semiconductor layers 26U. The dielectric layer may be formed by depositing CESL 70U over source/drains 62U, depositing ILD layer 72L over CESL 70L, and performing a planarization process, which may stop upon reaching gate structures (e.g., dummy gate stacks 430 thereof).

Referring to FIG. 10D, fabricating stacked device structure 10B may include performing a gate replacement process (i.e., replacing dummy gate stacks 430 with gates 90U (e.g., having gate dielectric 78U and gate electrode 80U)) and performing a channel release process, such as described above with reference to FIG. 9F. In some embodiments, fabrication includes removing dummy gate stacks 430 to form gate openings (e.g., by a selective etching process); removing semiconductor layers 162 exposed by the gate openings to form gaps/openings between semiconductor layers 164 (26U) and between semiconductor layers 164 (26U) and isolation structure 17B (e.g., by a selective etching process), thereby suspending semiconductor layers 164 (26U) over isolation structure 17B; and forming gates 90U that fill the gate openings and the gaps.

In some embodiments, forming device 12U may further include forming hard masks 92U over gates 90U, such as described above with reference to FIG. 9F. In some embodiments, fabricating stacked device structure 10B may include forming interconnects, such as gate contacts and/or source/drain contacts, of device 12U. For example, source/drain contacts may be formed in the dielectric layer (e.g., ILD layer 72U and/or CESL 70U) on source/drains 62U, such as described above with reference to FIG. 9F. In some embodiments, a source/drain via may be formed that electrically connects a respective source/drain 62U and a respective source/drain 62L. In such embodiments, the source/drain via may be physically and/or electrically connected to a first source/drain contact formed on the respective source/drain 62U and a second source/drain contact formed on the respective source/drain 62L.

Devices and/or structures described herein, such as stacked device structure 10A, stacked device structure 10B, device 12L, device 12U, transistor 20L, transistor 20U, etc. may be included in a microprocessor, a memory, other IC device, or combinations thereof. In some embodiments, devices and/or structures described herein, such as stacked device structure 10A, stacked device structure 10B, device 12L, device 12U, transistor 20L, transistor 20U, etc. described herein are a portion of an IC chip, a system on chip (SoC), or portion thereof, that includes various passive and active microelectronic devices, such as resistors, capacitors, inductors, diodes, p-type FETs (PFETs), n-type FETs (NFETs), metal-oxide semiconductor FETs (MOSFETs), complementary metal-oxide semiconductor (CMOS) transistors, bipolar junction transistors (BJTs), laterally diffused MOS (LDMOS) transistors, high voltage transistors, high frequency transistors, other devices, or combinations thereof.

The present disclosure provides for many different embodiments. An exemplary method includes forming a first stacked structure by receiving a first device component, receiving a second device component, and bonding a semiconductor layer stack of the first device component and the second device component. The first device component includes a first substrate, the semiconductor layer stack, and a release layer disposed between the first substrate and the semiconductor layer stack. The first stacked structure includes the semiconductor layer stack disposed between the release layer and the second device component. The method further includes, after the bonding, removing the first substrate and the release layer from the first stacked structure, and reusing the first substrate to form a second stacked structure. In some embodiments, the release layer is disposed on the first substrate after removing the first substrate and the release layer from the first stacked structure. In such embodiments, the method further includes reusing the release layer to form the second stacked structure or removing the release layer (e.g., by a planarization process, such as CMP) before reusing the first substrate.

In some embodiments, the release layer is formed of a two-dimensional material, and the first substrate and the release layer are removed by peeling. In some embodiments, the first device component further includes a silicon cap disposed between the release layer and the semiconductor layer stack, and the method further includes removing the silicon cap after removing the first substrate and the release layer from the first stacked structure. In some embodiments, the release layer is formed of a semiconductor oxide material, and the first substrate and the release layer are removed by laser treatment. In some embodiments, the first device component further includes a sacrificial layer disposed between the release layer and the semiconductor layer stack, and the method further includes removing the sacrificial layer after removing the first substrate and the release layer from the first stacked structure.

In some embodiments, the first device component is a device precursor for fabricating a first device, the second device component is a second device, and the method further includes processing the first stacked structure to form a device stack that includes the first device disposed over the second device. Processing the first stacked structure may include processing the device precursor to form the first device. In some embodiments, the first device component is a first device precursor for fabricating a first device, the second device component is a second device precursor for fabricating a second device, and the method further includes processing the first stacked structure to form a device stack that includes the first device disposed over the second device. Processing the first stacked structure may include processing the first device precursor and the second device precursor to form the first device and the second device, respectively.

Another exemplary method includes forming a two-dimensional material layer over a first substrate, forming a first multilayer stack over the two-dimensional material layer, and forming a stacked structure by bonding the first multilayer stack to a second multilayer stack. The second multilayer stack may be over a second substrate. The method further includes performing a peeling process to remove the first substrate and the two-dimensional material layer from the stacked structure. In some embodiments, forming the two-dimensional material layer over the first substrate includes forming a graphene layer. In some embodiments, forming the two-dimensional material layer over the first substrate includes forming a hexagonal boron nitride layer. In some embodiments, the method further includes forming a silicon cap over the two-dimensional material layer before forming the first multilayer stack and removing the silicon cap after performing the peeling process. In some embodiments, the stacked structure is a first stacked structure, and the method further includes reusing the first substrate. Reusing the first substrate may include forming a third multilayer stack over the first substrate and forming a second stacked structure that includes the third multilayer stack and the first substrate. In some embodiments, the stacked structure is a first stacked structure, the peeling process is a first peeling process, and the method further includes reusing the first substrate and the two-dimensional material layer. Reusing the first substrate and the two-dimensional material layer may include forming a third multilayer stack over the two-dimensional material layer; forming a second stacked structure that includes the third multilayer stack, the two-dimensional material layer, and the first substrate; and performing a second peeling process to remove the first substrate and the two-dimensional material layer from the second stacked structure. In some embodiments, a thickness of the first multilayer stack is about 10 nm to about 80 nm. In some embodiments, a thickness of the second multilayer stack is about 10 nm to about 80 nm. In some embodiments, a thickness of the third multilayer stack is about 10 nm to about 80 nm.

Another exemplary method includes forming a semiconductor oxide region over a first substrate, forming a first multilayer stack over the semiconductor oxide region, and forming a stacked structure by bonding the first multilayer stack to a second multilayer stack. The second multilayer stack is over a second substrate. The method further includes performing a laser treatment to remove the first substrate and the semiconductor oxide region from the stacked structure. In some embodiments, forming the semiconductor oxide region over the first substrate includes performing an oxygen treatment. In some embodiments, forming the semiconductor oxide region over the first substrate includes performing an implantation process. In some embodiments, the method further includes forming a sacrificial layer over the semiconductor oxide region before forming the first multilayer stack. The sacrificial layer is between the first multilayer stack and the semiconductor oxide region. In such embodiments, the method may further includes removing the sacrificial layer from the stacked structure by a planarization process after performing the laser treatment to remove the first substrate and the semiconductor oxide region. In some embodiments, the stacked structure is a first stacked structure, the semiconductor oxide region is a first semiconductor oxide region, the laser treatment is a first laser treatment, and the method further includes reusing the first substrate. Reusing the first substrate may include removing the first semiconductor oxide region from the first substrate after performing the first laser treatment to remove the first substrate and the first semiconductor oxide region from the first stacked structure, forming a second semiconductor oxide region over the first substrate, forming a third multilayer stack over the second semiconductor oxide region, forming a second stacked structure that includes the third multilayer stack and the first substrate, and performing a second laser treatment to remove the first substrate and the second semiconductor oxide region from the second stacked structure. In some embodiments, a thickness of the first multilayer stack is about 10 nm to about 80 nm. In some embodiments, a thickness of the second multilayer stack is about 10 nm to about 80 nm. In some embodiments, a thickness of the third multilayer stack is about 10 nm to about 80 nm.

Another exemplary method includes receiving a first device precursor and receiving a second device precursor. The first device precursor includes a first semiconductor layer stack disposed over a first substrate and a two-dimensional material disposed between the first substrate and the first semiconductor layer stack. The second device precursor includes a second semiconductor layer stack disposed over a second substrate. The method further includes bonding the first semiconductor layer stack and the second semiconductor layer stack to form a stacked structure. The stacked structure includes the first device precursor disposed over the second device precursor. The method further includes removing the first substrate and the two-dimensional material from the stacked structure. In some embodiments, the method further includes processing the stacked structure to form a first device and a second device. The first device may be disposed over the second device. In some embodiments, the method further includes forming the first device precursor. For example, the method may include forming the two-dimensional material (e.g., graphene or hexagonal boron nitride) over the first substrate and forming the first semiconductor layer stack over the two-dimensional material.

In some embodiments, the removing the first substrate and the two-dimensional material includes performing a peeling process. In some embodiments, the method further includes reusing the first substrate to form another stacked structure. In some embodiments, the method further includes reusing the two-dimensional material. In some embodiments, the first device precursor further includes a silicon capping layer disposed between the two-dimensional material and the first semiconductor layer stack, and the method further includes removing the silicon capping layer from the stacked structure. In some embodiments, the removing the silicon capping layer includes performing a chemical mechanical planarization process.

In some embodiments, the stacked structure is a first stacked structure, and, after removing the first substrate and the two-dimensional material from the first stacked structure, the method further includes forming a third semiconductor layer stack over the two-dimensional material. In such embodiments, a third device precursor may include the third semiconductor layer stack, the two-dimensional material, and the first substrate, and the two-dimensional material is disposed between the first substrate and the third semiconductor layer stack. In some embodiments, the method further includes bonding the third semiconductor layer stack and a fourth semiconductor layer stack to form a second stacked structure. The second stacked structure includes the third device precursor disposed over a fourth device precursor, and the fourth device precursor includes the fourth semiconductor layer stack disposed over a fourth substrate. In some embodiments, the method further includes removing the first substrate and the two-dimensional material from the second stacked structure.

In some embodiments, the two-dimensional material is a first two-dimensional material, and the stacked structure is a first stacked structure. In such embodiments, after removing the first substrate and the two-dimensional material from the first stacked structure, the method may further include removing the first two-dimensional material from the first substrate, forming a second two-dimensional material over the first substrate, and forming a third semiconductor layer stack over the second two-dimensional material. Further, in such embodiments, a third device precursor may include the third semiconductor layer stack, the second two-dimensional material, and the first substrate, and the second two-dimensional material may be disposed between the first substrate and the third semiconductor layer stack. In some embodiments, the method further includes bonding the third semiconductor layer stack and a fourth semiconductor layer stack to form a second stacked structure. The second stacked structure includes the third device precursor disposed over a fourth device precursor, and the fourth device precursor includes the fourth semiconductor layer stack disposed over a fourth substrate. In some embodiments, the method further includes removing the first substrate and the second two-dimensional material from the second stacked structure.

In some embodiments, bonding the first semiconductor layer stack and the second semiconductor layer stack to form the stacked structure includes forming a first bonding layer over the first semiconductor layer stack, forming a second bonding layer over the second semiconductor layer stack, and bonding the first bonding layer to the second bonding layer. In such embodiments, the first bonding layer and the second bonding layer may form a bonding structure, and the stacked structure may include the bonding structure disposed between the first device precursor and the second device precursor. In some embodiments, the first bonding layer is a first insulation (and/or isolation) layer (e.g., a first dielectric layer), the second bonding layer is a second insulation (and/or isolation) layer (e.g., a second dielectric layer), and the bonding structure is an insulation (and/or isolation) structure (e.g., a dielectric structure). In some embodiments, where the method further includes processing the stacked structure to form a first device and a second device, the insulation structure may separate at least a portion of the first device and the second device (e.g., channel regions and/or gate regions thereof). In some embodiments, a thickness of the first bonding layer is about 0.5 nm to about 50 nm. In some embodiments, a thickness of the second bonding layer is about 0.5 nm to about 50 nm. In some embodiments, a thickness of the bonding structure is about 1 nm to about 100 nm.

Another exemplary method includes receiving a first device precursor and receiving a second device precursor. The first device precursor includes a first semiconductor layer stack disposed over a first substrate and a release layer disposed between the first substrate and the first semiconductor layer stack. The second device precursor includes a second semiconductor layer stack disposed over a second substrate. The method further includes bonding the first semiconductor layer stack and the second semiconductor layer stack to form a stacked structure. The stacked structure includes the first device precursor disposed over the second device precursor. The method further includes removing the first substrate and the release layer from the stacked structure. In some embodiments, the method further includes processing the stacked structure to form a first device and a second device. The first device may be disposed over the second device. In some embodiments, the method further includes reusing the first substrate to form another stacked structure. In some embodiments, removing the first substrate and the release layer includes performing a laser treatment. In some embodiments, the laser treatment includes exposing the stacked structure to infrared (IR) laser. In some embodiments, a wavelength of a laser implemented during the laser treatment is about 4 nm to about 10 nm.

In some embodiments, the release layer is a semiconductor oxide layer. In some embodiments, the method further includes forming the first device precursor, which may include performing an oxygen treatment to form the semiconductor oxide layer over the first substrate before forming the first semiconductor layer stack and forming the first semiconductor layer stack over the semiconductor oxide layer. In some embodiments, the stacked structure is a first stacked structure, and the semiconductor oxide layer is a first semiconductor oxide layer. In such embodiments, after removing the first substrate and the release layer from the first stacked structure, the method may further include forming a second semiconductor oxide layer over the first substrate and forming a third semiconductor layer stack over the second semiconductor oxide layer. A third device precursor includes the third semiconductor layer stack, the second semiconductor oxide layer, and the first substrate, and the second semiconductor oxide layer is disposed between the first substrate and the third semiconductor layer stack. In some embodiments, the method further includes bonding the third semiconductor layer stack and a fourth semiconductor layer stack to form a second stacked structure. The second stacked structure includes the third device precursor disposed over a fourth device precursor, and the fourth device precursor includes the fourth semiconductor layer stack disposed over a fourth substrate. In some embodiments, the method further includes removing the first substrate and the second semiconductor oxide layer from the second stacked structure.

In some embodiments, the release layer is a doped layer. In some embodiments, the method further includes forming the first device precursor, which may include performing an implantation process to form the doped layer at a top surface of the first substrate before forming the first semiconductor layer stack and forming the first semiconductor layer stack over the doped layer. In some embodiments, the stacked structure is a first stacked structure, and the doped layer is a first doped layer. In such embodiments, after removing the first substrate and the release layer from the first stacked structure, the method may further include removing the first doped layer from the first substrate, forming a second doped layer over the first substrate, and forming a third semiconductor layer stack over the second doped layer. A third device precursor includes the third semiconductor layer stack, the second doped layer, and the first substrate, and the second doped layer is disposed between the first substrate and the third semiconductor layer stack. In some embodiments, the method further includes bonding the third semiconductor layer stack and a fourth semiconductor layer stack to form a second stacked structure. The second stacked structure includes the third device precursor disposed over a fourth device precursor, and the fourth device precursor includes the fourth semiconductor layer stack disposed over a fourth substrate. In some embodiments, the method further includes removing the first substrate and the second doped layer from the second stacked structure.

In some embodiments, bonding the first semiconductor layer stack and the second semiconductor layer stack to form the stacked structure includes forming a first bonding layer over the first semiconductor layer stack, forming a second bonding layer over the second semiconductor layer stack, and bonding the first bonding layer to the second bonding layer. In such embodiments, the first bonding layer and the second bonding layer may form a bonding structure, and the stacked structure may include the bonding structure disposed between the first device precursor and the second device precursor. In some embodiments, the first bonding layer is a first insulation (and/or isolation) layer (e.g., a first dielectric layer), the second bonding layer is a second insulation (and/or isolation) layer (e.g., a second dielectric layer), and the bonding structure is an insulation (and/or isolation) structure (e.g., a dielectric structure). In some embodiments, where the method further includes processing the stacked structure to form a first device and a second device, the insulation structure may separate at least a portion of the first device and the second device (e.g., channel regions and/or gate regions thereof). In some embodiments, a thickness of the first bonding layer is about 0.5 nm to about 50 nm. In some embodiments, a thickness of the second bonding layer is about 0.5 nm to about 50 nm. In some embodiments, a thickness of the bonding structure is about 1 nm to about 100 nm.

Another exemplary method includes depositing a two-dimensional material layer over a first wafer (also referred to as a first substrate), depositing a first epitaxial stack over the two-dimensional material layer, depositing a second epitaxial stack over a second wafer (also referred to as a second substrate), bonding the first wafer to the second wafer, and peeling the first wafer away from the first epitaxial stack after the bonding. In some embodiments, the method further includes depositing a silicon capping layer over the first wafer before depositing the first epitaxial stack. In some embodiments, the method further includes depositing a third epitaxial stack over the first wafer after peeling the first wafer away from the first epitaxial stack.

Another exemplary method includes forming a release layer over a first wafer (also referred to as a first substrate), depositing a first epitaxial stack over the release layer, depositing a second epitaxial stack over a second wafer (also referred to as a second substrate), bonding the first wafer to the second wafer, and performing a laser treatment to heat the release layer, such that the first wafer is removed from the first epitaxial stack after the bonding. In some embodiments, the method further includes depositing a third epitaxial stack over the first wafer after the laser treatment. In some embodiments, the release layer is a semiconductor oxide layer, such as silicon oxide. In some embodiments, the laser treatment applies a laser to a backside of the first wafer, the laser penetrates through the first wafer to the semiconductor oxide layer, and the semiconductor oxide layer absorbs the laser. In some embodiments, a coefficient of thermal expansion (CTE) of the release layer is greater than a CTE of the first wafer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first stacked structure by:
receiving a first device component, wherein the first device component includes a first substrate, a semiconductor layer stack, and a release layer disposed between the first substrate and the semiconductor layer stack,
receiving a second device component,
bonding the semiconductor layer stack and the second device component, wherein the first stacked structure includes the semiconductor layer stack disposed between the release layer and the second device component; and
after the bonding, removing the first substrate and the release layer from the first stacked structure; and
reusing the first substrate to form a second stacked structure.

2. The method of claim 1, wherein the release layer is disposed on the first substrate after removing the first substrate and the release layer from the first stacked structure, the method further comprising reusing the release layer to form the second stacked structure.

3. The method of claim 1, wherein the release layer is disposed on the first substrate after removing the first substrate and the release layer from the first stacked structure, the method further comprising removing the release layer before reusing the first substrate.

4. The method of claim 1, wherein the release layer is formed of a two-dimensional material, and the first substrate and the release layer are removed by peeling.

5. The method of claim 4, wherein:
the first device component further includes a silicon cap disposed between the release layer and the semiconductor layer stack; and
the method further includes removing the silicon cap after removing the first substrate and the release layer from the first stacked structure.

6. The method of claim 1, wherein the release layer is formed of a semiconductor oxide material, and the first substrate and the release layer are removed by laser treatment.

7. The method of claim 6, wherein:
the first device component further includes a sacrificial layer disposed between the release layer and the semiconductor layer stack; and
the method further includes removing the sacrificial layer after removing the first substrate and the release layer from the first stacked structure.

8. The method of claim 1, wherein:
the first device component is a device precursor for fabricating a first device;
the second device component is a second device; and
the method further includes processing the first stacked structure to form a device stack that includes the first device disposed over the second device, wherein the processing the first stacked structure includes processing the device precursor to form the first device.

9. The method of claim 1, wherein:
the first device component is a first device precursor for fabricating a first device and the second device component is a second device precursor for fabricating a second device; and
the method further includes processing the first stacked structure to form a device stack that includes the first device disposed over the second device, wherein the processing the first stacked structure includes processing the first device precursor and the second device precursor to form the first device and the second device, respectively.

10. A method comprising:
forming a two-dimensional material layer over a first substrate;
forming a first multilayer stack over the two-dimensional material layer;
forming a stacked structure by bonding the first multilayer stack to a second multilayer stack, wherein the second multilayer stack is over a second substrate; and
performing a peeling process to remove the first substrate and the two-dimensional material layer from the stacked structure.

11. The method of claim 10, wherein the forming the two-dimensional material layer over the first substrate includes forming a graphene layer.

12. The method of claim 10, wherein the forming the two-dimensional material layer over the first substrate includes forming a hexagonal boron nitride layer.

13. The method of claim 10, further comprising:
forming a silicon cap over the two-dimensional material layer before forming the first multilayer stack; and
removing the silicon cap after performing the peeling process.

14. The method of claim 10, wherein:
the stacked structure is a first stacked structure; and
the method further includes reusing the first substrate, wherein the reusing the first substrate includes forming a third multilayer stack over the first substrate and forming a second stacked structure that includes the third multilayer stack and the first substrate.

15. The method of claim 10, wherein:
the stacked structure is a first stacked structure;
the peeling process is a first peeling process; and
the method further includes reusing the first substrate and the two-dimensional material layer, wherein the reusing the first substrate and the two-dimensional material layer includes:
forming a third multilayer stack over the two-dimensional material layer,
forming a second stacked structure that includes the third multilayer stack, the two-dimensional material layer, and the first substrate, and
performing a second peeling process to remove the first substrate and the two-dimensional material layer from the second stacked structure.

16. A method comprising:
forming a semiconductor oxide region over a first substrate;
forming a first multilayer stack over the semiconductor oxide region;
forming a stacked structure by bonding the first multilayer stack to a second multilayer stack, wherein the second multilayer stack is over a second substrate; and
performing a laser treatment to remove the first substrate and the semiconductor oxide region from the stacked structure.

17. The method of claim 16, wherein the forming the semiconductor oxide region over the first substrate includes performing an oxygen treatment.

18. The method of claim 16, wherein the forming the semiconductor oxide region over the first substrate includes performing an implantation process.

19. The method of claim 16, further comprising:
forming a sacrificial layer over the semiconductor oxide region before forming the first multilayer stack, wherein the sacrificial layer is between the first multilayer stack and the semiconductor oxide region; and
removing the sacrificial layer from the stacked structure by a planarization process after performing the laser treatment to remove the first substrate and the semiconductor oxide region.

20. The method of claim 16, wherein:
the stacked structure is a first stacked structure;
the semiconductor oxide region is a first semiconductor oxide region;
the laser treatment is a first laser treatment; and
the method further includes reusing the first substrate by:
removing the first semiconductor oxide region from the first substrate after performing the first laser treatment to remove the first substrate and the first semiconductor oxide region from the first stacked structure,
forming a second semiconductor oxide region over the first substrate,
forming a third multilayer stack over the second semiconductor oxide region,
forming a second stacked structure that includes the third multilayer stack and the first substrate, and
performing a second laser treatment to remove the first substrate and the second semiconductor oxide region from the second stacked structure.
